(19) United States
(12) Patent Application Publication
(10) Pub. No.: US 2026/0044281 A1
(43) Pub. Date: Feb. 12, 2026

(54) Utilizing Data Embedded in Address Streams

(71) Applicant: Micron Technology, Inc., Boise, ID (US)

(72) Inventor: David Andrew Roberts, Wellesley, MA (US)

(73) Assignee: Micron Technology, Inc., Boise, ID (US)

(21) Appl. No.: 18/799,622

(22) Filed: Aug. 9, 2024

(51) Int. Cl. G06F 3/06

(52) U.S. Cl. CPC G06F 3/0656; G06F 3/0604; G06F 3/0679

(57) ABSTRACT

Apparatuses and techniques for utilizing data embedded in address streams are described. With a memory trace, it can be challenging to use physical probes or accommodate the requisite bandwidth to record both address and data information, so the data is often omitted. The address information alone, however, is sometimes insufficient for analysis. This document describes embedding data in the address stream to provide metadata or other information that can lend context to the addresses in the address stream. The existence of data in the address stream can be communicated using, for example, a mailbox, a preamble message in a messaging protocol, a checksum, repetitive transmissions, or combinations thereof. The embedded data can also provide real-time information. To enable real-time processing, a hardware architecture includes multiple decoders so that multiple permutations of address sets can be analyzed in real time. The real-time information can include operational indications to improve memory performance.

### BACKGROUND

New designs for memory devices are being developed to enable faster, less-expensive, or more-reliable computing. To ensure that a new memory design will function as expected, the memory design is tested. For example, analyzing signal traces of a memory bus that is coupled to a memory device can help when evaluating a new memory design. A testing apparatus attaches physical probes to pins or wires on the memory bus and provides input to a logic analyzer that records signals as they appear on the memory bus during a memory test. The recorded signals can be input to a simulator for replaying how the new memory design functions in response to memory requests made during the test. This memory testing process has become more challenging, however, as memory devices have become more complex.

### BRIEF DESCRIPTION OF THE DRAWINGS

Apparatuses of and techniques for utilizing data embedded in address streams are described with reference to the following drawings. The same numbers are used throughout the drawings to reference like features and components:

FIG. 1 illustrates an example computer in which various techniques, devices, and circuitries described in this document can operate;

FIGS. 2-1 and 2-2 each illustrate an example scheme in which a mailbox is referenced by, or linked to, data in an example address stream;

FIG. 3 illustrates another example computer that can utilize data embedded in an address stream;

FIG. 4 illustrates an example address stream that enables identification of data using an error detection checksum;

FIGS. 5-1 and 5-2 illustrate additional example environments, including computing apparatuses and circuitries, in which various techniques and devices described in this document can operate;

FIG. 6 illustrates example operations performed by a computing system that embeds data in an address stream;

FIG. 7 illustrates example operations performed by a system that extracts data embedded in an address stream;

FIG. 8 illustrates example aspects of a memory address that can be used to communicate data, including to establish or use a mailbox;

FIG. 9-1 illustrates an example set of memory addresses that can jointly communicate data using a mailbox or a check code;

FIG. 9-2 illustrates multiple different example memory allocations for at least one mailbox;

FIG. 10 illustrates an example architecture for obtaining data from a memory address stream using a check code, which processing can include using a mailbox;

FIG. 11 illustrates an example architecture for filtering memory addresses based on a mailbox value that is indicative of a mailbox memory allocation;

FIG. 12 illustrates an example method for utilizing data embedded in address streams; and FIG. 13 illustrates another example method for utilizing data embedded in address streams.

### DETAILED DESCRIPTION

### Overview

Techniques and devices are described for embedding data within an address stream on an interconnect, such as a memory bus of a computer. Here, physical lines that communicate an address stream can be made to communicate data, which is interspersed amongst or referenced through bits of the address stream. Address lines of the interconnect can be dedicated to propagating the address stream or selectively employed to propagate the address stream (e.g., in a time-division manner that is shared between the address stream and a logically separate data stream). Bits of the address stream typically convey addresses (e.g., memory pages and offsets) used in the execution of memory read or write operations. Data to be read or written during execution of the operations, however, is communicated separately through a data stream, which may be on the same physical lines or on different physical lines as compared to the address stream. To avoid the complexities of tracing a data stream contemporaneously with the tracing of an address stream and any command lines, this document describes configuring the address stream to carry data at least occasionally, which data can then be automatically recorded as part of the trace of the address stream. Data extracted from within this extra, logical data channel can be used to enhance the address and other information obtained in the memory trace. Such enhancements can include, for example, performing a function or determining data and control dependencies, even without monitoring the data stream.

Different types of data can be embedded in a data stream. A program or system state, a thread or process identifier, an instruction or program counter, and a function or task identifier are some examples of data that can be embedded in an address stream. The data can be “directly” embedded in the address stream as described herein by using at least a portion of a memory address. Additionally or alternatively, data can be “indirectly” communicated by embedding data in the address stream using a pointer or reference. To do so, an embedded pointer or reference links to a “mailbox” or other portion of a memory that is allocated for the purpose of communicating data through the address stream.

Consider a test engineer or technician evaluating a memory for a computer through signal-trace-analysis and a memory-system simulation. Software instrumentation executing at a host or memory device may output a memory trace to a file. Alternatively, physical probes attached to command lines or address lines may be used to send signals to a recipient that records the signals of the address stream as a trace, typically without recording a corresponding data stream. The recipient of the memory trace may be a program, a logic analyzer, a routine, a system on chip (SoC), analysis circuitry at a memory device, or another component or entity. The output received from the probes or software instrumentation can be recorded by the recipient in association with timestamps. The recorded signals or trace file may be fed to the memory-system simulation for subsequent playback and signal-trace-analysis. The simulation's playback of the command lines or address stream offers insights into how the memory design performs when connected to a host device of a computer system.

Useful control dependencies may be discoverable from an inspection of the data stream; however, it may not be feasible to trace the data stream while also tracing the address stream and control lines because of limitations in probing or monitoring by a recipient. For example, existing logic analyzers or other recipients of probed signals have a finite number of input channels. Generating a complete memory trace, including both the address stream and a corresponding data stream, even if possible, would require a complex logic analyzer, an excessive number of probes, and significant storage space. Ignoring the data stream is one way to curtail costs and complexities in performing signal-trace-analysis. Unfortunately, without the data stream, some data or control dependencies are undiscoverable during simulation playback. Moreover, a computer system often runs multiple programs (e.g., applications or processes) and threads with interleaved memory activity. It is therefore difficult to precisely correlate software events with memory activity without having context about the data as well as the addresses of memory activities appearing on the memory bus.

An example computing system described herein embeds data (e.g., context information) in an address stream by direct injection into the address stream or by indirect injection using an indication of the data in the address stream. The data may provide context for addresses appearing within the address stream at the corresponding point in time. The context can be recorded for use during subsequent playback and/or analysis of the trace, without requiring additional instrumentation, probes, lines, wires, pins, or other hardware, beyond that which is already used to monitor an address stream. The data can also be used to convey other information, such as a message from a program executing at the host device to a memory device or other recipient of the address stream, without modifying hardware. For instance, the data can be used to convey control dependencies, which can be used to produce more-accurate simulations, among other purposes. When output on existing address wires of an address bus, the embedded data can be useful to validate a new memory or to control a memory in ways that addresses alone cannot. As such, although normally an address stream only includes addresses, example computing systems as described herein are configured to selectively embed data within their address streams, directly or indirectly, and in accordance with certain principles set forth herein.

An example system includes a host device connected to a memory device over an interconnect. The host device regularly sends signals over the interconnect, for example, by transmitting an address stream and control commands on address and control lines, respectively. The host device also sends signals over the interconnect by transmitting a corresponding data stream on data lines. In accordance with principles described herein, the host device can additionally or alternatively send at least an indication of data through the address stream, but the indication appears to a logic analyzer or other recipient like any other address on the memory bus. The host device outputs the data onto a hidden or logical channel that is conceptually overlaid on the address lines and interspersed within the address stream.

Probing the address lines to trace the address stream likewise traces the data that the host device sends through the logical channel. As such, when monitored, the data or indication of data within the logical channel is traced in the same way addresses outside the logical channel are preserved. To a recipient of the address stream, this embedded data can provide context or clues for debugging or for determining how the system, including a memory device, performs. From the data, control or data dependencies, which are normally undiscoverable without a trace or other understanding of a corresponding data stream, are identifiable from the trace of the address stream.

The embedded data can supplement or enhance a memory-system simulation. For example, a logic analyzer monitoring an address stream can control a function (e.g., an alarm or alert) based on the data extracted from the address stream. During playback, the simulation can omit from a memory trace the memory traffic related to the embedded data if the omission is desirable to conceal (e.g., from an analyzer) that data was communicated in the address stream. For instance, the data-related memory traffic revealed during signal-trace-analysis of the address stream can be excluded during simulation playback to prevent an incorrect simulation playback. To do so, memory traffic referencing embedded data may be removed from a memory trace before playback by a simulator. While the data extracted from the address stream may be omitted from the simulated playback of the address stream, the data can be output alongside the addresses of the address stream, which can improve fidelity of a memory-system simulation. Sending data through an address stream using the techniques and devices described herein is not limited to improving memory-system simulations, however, as is described next.

The described techniques and devices additionally or alternatively allow data to be embedded in an address stream at any time, and for any reason, not merely to support test and evaluation. For example, some memory architectures specify dedicated input and output channels to pass tracking information over a memory bus between a host device and a memory device. Other memory devices may provide internal registers that obtain contextual data written by a host device. Examples of such contextual data include prefetch hints or non-cacheable address flags, and the memory devices can use the contextual data as part of the execution of one or more memory operations. Although both techniques enable data communication, both also add complexity to the hardware components of a system, which can greatly increase costs. In contrast, a host device of an example computing system as described herein can convey data on the existing address lines of a memory bus, including whenever a physical sideband channel or access to a data stream is not available.

As mentioned, data can be directly or indirectly injected into the address stream. Data may be communicated directly within the address stream by causing the host device to, for instance, invoke a software library function that automatically manipulates addresses being sent on the memory bus such that the addresses convey at least an indication of data. The software library can include an initialization function, which, responsive to being called by the host device, sends a recipient of the address stream (e.g., a memory device or logic analyzer) information about when or how embedded data will appear in the address stream. Initialization may not be necessary in all implementations; performance, however, can be improved through initialization in some scenarios by effectively priming the recipient to recognize data when the data appears in the address stream. After initialization, the host device can call a send-message or send-packet function of the software library to embed in the address stream data that is input as a parameter to the called function. Alternatively, the host device may use the described techniques and methods to communicate data (e.g., context information, commands, or other information) to the memory device using data embedded in an address stream without calling a library function.

With respect to indirect data injection, an indication of the data embedded in an address stream may itself represent bits of information or metadata that appear to be addresses but that are not referenced to a mailbox location. If, however, a mailbox is used, a program can pre-allocate a memory area as the mailbox and share the mailbox location with the memory device, logic analyzer, or other recipient of the embedded data. In this way, there does not need to be any initialization or upfront coordination between the recipient and the host device. Instead, whenever an address mapping into the already-allocated mailbox is identified within the address stream, the recipient treats the non-mailbox bits (e.g., packet or offset bits) as embedded data due to the reference to the mailbox. Because the memory of the mailbox is privately allocated and owned by the program, and because the size of the mailbox may be small and contained to only one or a few pages in memory, there will likely not be any interfering or unintended memory requests within the mailbox. By establishing a mailbox and/or communicating using a check code (e.g., a checksum), examples of which are described below, any program can establish a reliable and private mailbox for application-specific data, for example.

Embedding data within an address stream can be effective to transmit data from a host device to a recipient. A processor or a memory controller of a host device, or a component of a memory device, may act on data communicated through an address stream, such as by directing caches, prefetchers, or other hardware of the computer or by executing a processing-in-memory (PIM) operation. If the address stream is being probed, a separate physical test probe is not necessary to extract the embedded data that becomes part of the address stream. To utilize the embedded data, the recipient may include logic that recognizes a transmission of the data appearing in the address stream. By monitoring the address portion of a memory bus, the logic may identify embedded data in response to identifying a particular address pattern, which pattern was not initiated by a test program.

Another way to embed data through an address stream is by indirectly embedding the data, such as by establishing a mailbox. Using a mailbox increases the throughput of the hidden channel, as more data can be conveyed via the mailbox in a shorter amount of time or in fewer memory-bus cycles than if the data is embedded directly. To embed data indirectly within an address stream, a program can cause a host device to allocate a contiguous portion of memory equal to an intended size (e.g., a four-kilobyte page) for the mailbox. The program may repeat, within a particular window (e.g., a window that is based on elapsed time or number of memory address transmissions), a pattern of addresses (e.g., a page address with one or more offsets) in the address stream to indicate where the mailbox is being designated for future data transmissions. When the pattern appears in the address stream within the allowed window, the memory device or other recipient of the address stream automatically determines that all subsequent addresses that reference a page or pages of memory corresponding to the mailbox are indications of data embedded by a program. For example, rather than an address for a memory request, the address stream may carry bits that reference the mailbox and include other bits (e.g., offset bits) having the embedded data. Thus, the embedded data can be obtained from the mailbox by detecting within the address stream address bits of the mailbox location (e.g., an address corresponding to a page or other memory range) and extracting the associated additional bits as the embedded data. Using a mailbox as a reference may not, however, be necessary in some example computing systems.

Optionally, an indication of data embedded in an address stream may include a checksum or other check code posing as at least part of one of the addresses within a pattern of addresses used to convey the data or the indication of data. In some cases, the checksum enables the recipient to determine a correct order to multiple parts of the data, for example, when transmission of an indication of data requires multiple memory cycles of the address stream. The ability to reorder parts is helpful in case the order is altered based on how the memory bus is managed by the memory controller of the host device and/or the memory device, each of which may be outside a sender program's control. The checksum verification process fails for a group of addresses if no combination of addresses in a group of addresses within the address stream can be ordered to satisfy a checksum that is part of a remaining address in the group. Nonetheless, a checksum may not be necessary in some example computing systems where reliability or the likelihood of reordering is less of a concern.

Also described herein are messaging protocols that can be implemented independent of, or in combination with, a mailbox and checksum to convey an indication of data embedded within an address stream. The messaging protocol includes a preamble or postamble message, either of which is identifiable from a repeating pattern of addresses in the address stream, which can be implemented in manners similar to how a mailbox can be identified as described herein. The preamble or postamble messages bound the program's indication of data, which appears as a payload message distributed across one or more memory cycles of the address stream. The preamble message represents a header or start of the payload message, and the postamble message conveys an end or tail of the payload message. Non-cacheable byte read or write instructions executed by the program can cause the repeating patterns associated with the preamble or postamble messages to be present or identifiable outside the host device within the address stream. The pattern can be present as a predefined distribution of addresses or a predefined distribution of deltas (e.g., inter-address differences) between addresses.

The payload message includes a sequence of addresses that encode the indication of data. The sequence of addresses belonging to the payload message appear in the address stream after the preamble message and before the postamble message if one or both are used. These address sequences are generated to be uncommon; each has almost no chance of occurring on the memory bus as part of a series of regular memory requests. The unique sequences are thus readily detectable by a recipient of the address stream, such as a memory device or a trace-reader program. As mentioned, addresses that make up the sequence in the payload message may be reordered on the memory bus, for instance, by a memory controller. The correct sequence of addresses is attainable if the payload message includes a checksum or a set of sequence values from which the correct order of addresses can be derived.

Other implementations of the example messaging protocol can use a mailbox to support indirect communication of data through the address stream. Referencing the mailbox enables a sender to ignore addresses outside of the mailbox range, reducing the number of memory accesses to be considered in the decoding process to identify the transmitted payloads, thus reducing the computational burden for decoding. Using a mailbox also reduces the likelihood of a “false positive” in which other memory requests that are not part of a message payload may be misinterpreted as being part of a payload message. A program can directly embed a payload of data within a memory address using bits beyond those corresponding to the bits of the mailbox, for example, including one or more least-significant-bits (LSBs). Initially, instead of actual data, the payload can represent a pointer (e.g., an address to a physical page or other region of memory) for the mailbox that is to be referenced to communicate the desired data. The program may output the payload message with the mailbox pointer between sending preamble and postamble messages if both are used, for instance. The trace-reader program, the memory device, or other recipient of the address stream can therefore determine from the payload the region of memory allocated to the program for the mailbox. A subsequent payload message, even without a preamble or postamble message, can reference the mailbox region automatically to trigger the recipient to identify data, indirectly, by extracting the additional bits from within a memory address that are not used to identify the memory region.

In some cases, a program writes data to a mailbox at runtime to communicate with a recipient. The recipient of the address stream obtains data from the mailbox when the mailbox region appears in the address stream. The mailbox can be monitored without the overhead of communicating and interpreting preamble or postamble messages once the mailbox is established. Devices monitoring the address stream can trigger internal functions that act on embedded data in response to identifying an address within the mailbox (e.g., the address of a designated memory region) from the address stream.

Using a predetermined mailbox, rather than establishing the mailbox through the messaging protocol, enables the sender and recipient to begin encoding and decoding embedded data more quickly and with less messaging overhead. Predetermining the mailbox region avoids having to exchange a preamble message or postamble message, either of which can be anywhere in the address stream, as well as interleaved with many other unrelated memory requests. Predetermining a mailbox that is already allocated to the program may be simple and effective for some systems; however, other example systems may further promote stability, reliability, and security by bounding each payload of data with a preamble or postamble using the messaging protocol or by using a check code that indicates associated data portions and a corresponding order.

Whether established ahead of time or through the messaging protocol, once the location of a mailbox is determined, data can be retrieved from an address stream by accessing (e.g., reading from or writing to) the mailbox's page or other memory region. For example, the LSBs of an address to a four-kilobyte-sized page can contain up to twelve bits of data in each memory address of an address stream recorded for a memory trace. The minimum size of a memory (e.g., a DRAM DIMM) data transfer (sometimes referred to as a “burst”) may be sixty-four (64) bytes. The six LSBs for offset addressing within the burst may not be communicated on the memory bus during read or write operations. For write operations, the mailbox can be identified by monitoring write byte-mask bits to preserve the LSBs. Or if using read operations, because each page addressing may leave 12 bits, each offset may communicate six (e.g., twelve minus six) bits of data per read operation.

Because it may be desirable to work with eight-bit checksums or other check codes, such as for ease in encoding or decoding the checksums in a computer system, some implementations may use a mailbox size larger than a 4 KB page (e.g., four times larger) to reduce the number of bits used to identify the mailbox and to increase the quantity of bits available for the payload by two bits, e.g., log2 (4). To achieve an eight-bit checksum, four pages of four kilobytes of memory per page may be used as a mailbox, which results in a memory region having a 16 KB size. The payload messages that result from a 16 KB mailbox are eight-bit “byte-sized” offsets within the mailbox, whether a given offset contains desired information or a checksum, either of which can be eight bits in such implementations. Therefore, allocating a larger mailbox that is greater in size than a single 4 KB page can increase the number of offset bits available to convey embedded data per memory address transmission, and such allocations can ensure each data item or checksum in a payload message can occupy a desired number of bits, such as a byte.

A memory region can be allocated to a mailbox in different manners relative to a memory region that is being used by a program for data of the program. In some cases, a mailbox can be separate from the data memory region of the program. This can simplify the detection of embedded data at a receiving device because there is less to no overlap in “true” memory requests as compared to memory requests having data embedded in the address stream. In other cases, the allocated memory region for a mailbox can overlay the data memory region. With non-destructive reads as the memory requests that provide the virtual data channel, no program data is adversely affected, and the mailbox does not incur a memory space overhead penalty. Further, overlaying a mailbox on the program data can facilitate using a larger mailbox that reduces spurious prefetching invocations. In these manners, a mailbox may be flexibly established based on one or more example priorities, such as certainty of detection of the embedded data, lower memory utilization, or impact on prefetching.

Once a mailbox has been allocated, a receiving device, such as a memory device or logic analyzer, is responsible for determining if a memory address contains data. Performing this determination in real time with software is challenging due to its computational demands. This document therefore describes a hardware-based approach to detecting embedded data. In example implementations, a device receives a stream of memory addresses, which can be stored in a memory. The memory address stream can be analyzed in a sliding temporal window that covers a predetermined quantity of memory addresses. This predetermined quantity may account for a maximum number of related memory addresses to be decoded (e.g., data packet(s) plus check code packet) in conjunction with some allowed quantity of memory addresses that may be interspersed by other program threads, memory request reordering, and so forth.

A quantity of decoders may be determined based on the predetermined quantity of memory addresses (n) in the sliding window and the maximum number of related memory addresses (r) planned for a given scenario. This quantity of decoders can cover different potential orderings based on a permutation analysis, such as nPr. This enables the hardware to substantially simultaneously search for each potential set of related memory addresses. The decoding analysis can be further facilitated by assigning each decoder of multiple decoders to a respective buffer of multiple buffers, with each buffer storing at least part of the predetermined quantity of memory addresses in a different order. Alternatively, certain buffers may store the memory addresses in the same order, but the corresponding decoder operates on them in different orders by loading bits from different ordered storage locations.

Using an algorithmic checking procedure, such as one based on a cyclic redundancy check (CRC) and CRC code, the multiple decoders can search for embedded data in real time. In some cases, with an established mailbox, the decoders can be fed memory addresses that are mapped to the mailbox such that any matches detect embedded data. However, in addition to identifying embedded data once a mailbox has been detected, the hardware can perform a mailbox detection procedure. For example, the hardware can decode the packet portion of memory addresses having multiple different potential mailbox-indicating address portions searching for one or more payloads that match with a check code in a different payload. Further, the system may institute a threshold number of mailbox detections (e.g., three detections within some time period or number of memory addresses) before the mailbox is considered to be established. In these manners, in an environment that creates a virtual data channel using memory addresses, hardware can be employed to keep pace with the real-time flow of a stream of memory addresses.

In other example implementations, a virtual data channel that is embedded in the addresses of memory requests can be used to provide information to a memory device during operation. Such information may provide a command, an instruction, a hint, and so forth regarding a current operational situation. In some cases, a program can insert an operational indication into an address stream, such as by calling a library that can create a memory request with the appropriate address bits. As an example of an operational indication, a program can indicate the presence of a memory object, which is otherwise opaque to the memory device.

Based on such an object indication, the memory device can engage in memory-side object tracking, such as by associating observed behaviors with that object indication. Responsive to detecting the object indication a subsequent time, the memory device can predict that the behaviors will recur. Accordingly, the memory device can support such behaviors by prefetching data, requesting that the host device employ a different memory pattern across memory banks, and so forth. Generally, a memory device may record a history of per-object statistics and predict upcoming changes to object behavior based on the statistics so that control parameters can be reconfigured in advance for better performance when the same program object is again allocated in memory. In these manners, memory performance can be improved by embedding data, including operational indications for instance, in memory address streams. These and other implementations are described herein.

### Example Environment

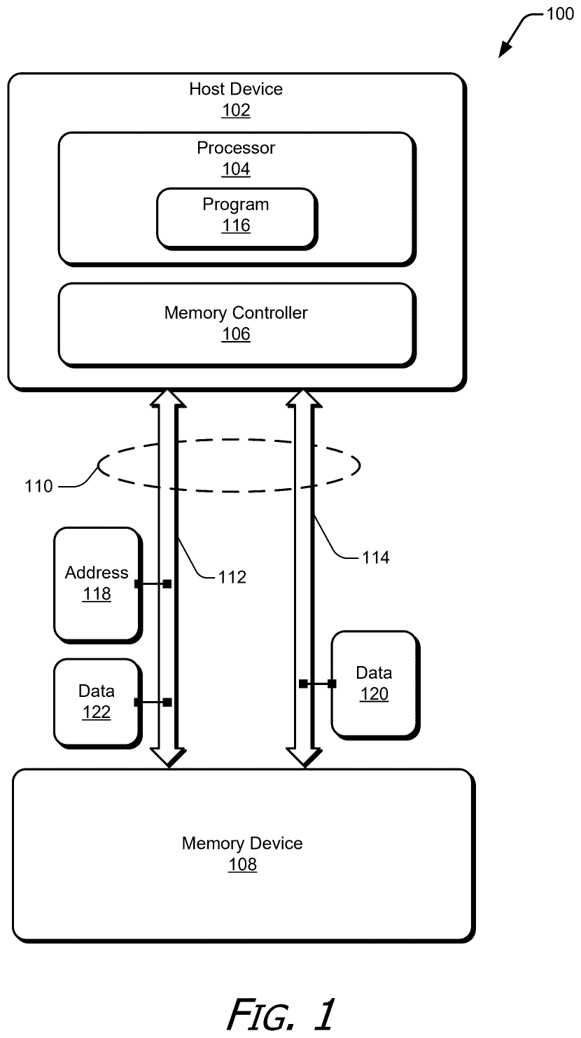

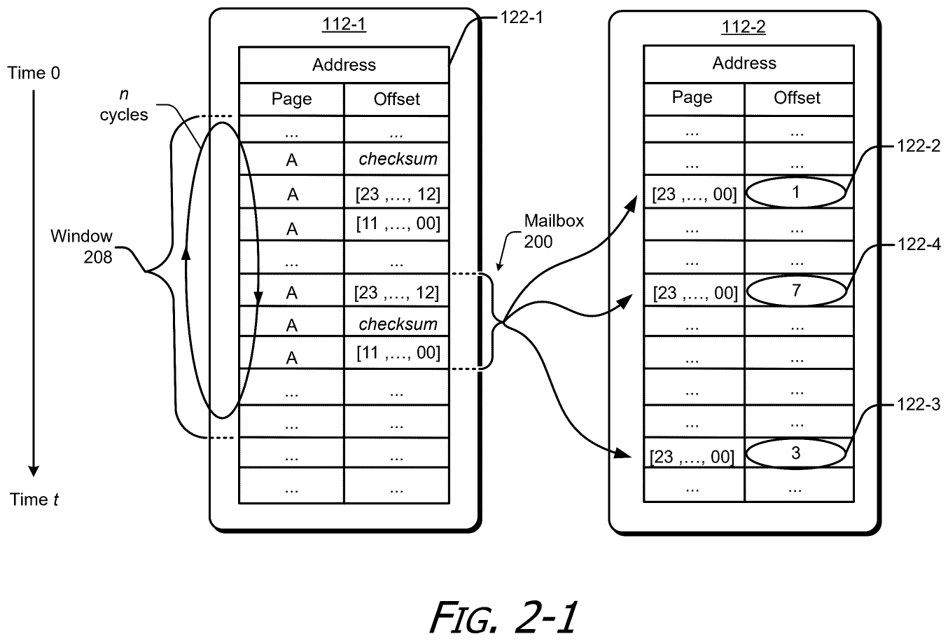

FIG. 1 illustrates an example computer 100 in which various techniques and devices described in this document can operate. The computer 100 includes a host device 102, which has one or more processors 104 and at least one memory controller 106, and a memory device 108 (referred to simply as “a memory 108”). In some examples, memory controller 106 may be an aspect of, and may reside on or within, the one or more processors 104. The computer 100 further includes an interconnect 110, which may be implemented as, for instance, a memory bus 110. The computer 100 can be any type of computing device, computing equipment, computing system, or electronic device which can utilize a channel for embedding data in an address stream.

As shown, the host device 102 and the memory device 108 are each coupled to the memory bus 110. Thus, the host device 102 and the memory device 108 are coupled one to the other via the memory bus 110. The processors 104 execute instructions that cause the memory controller 106 of the host device 102 to send signals on the memory bus 110. The host device 102 is configured to send an indication of data, such as a preamble message, a postamble message, a payload message, or the like as later described, within an address stream communicated on the memory bus 110. This communication can include addresses as well as an indication of data, sent over the memory bus 110 as part of an address stream 112. Put another way, the data refers to information other than a memory address for a (read or write) memory request. An indication of the data therefore, includes any machine or human recognizable feature, which appears in the address stream 112 to convey data, specifically, data other than an address to support a read or write memory request.

Thus, the memory bus 110 can include or provide a conduit for an address stream 112 or a data stream 114, or both. The address stream 112 includes or can be realized using a group of address wires, and the data stream 114 can encompass a different group of wires of the memory bus 110, referred to as data wires herein. The memory bus 110 can include additional wires or wireless connections; for example, a wired or wireless control bus may carry status or command signals exchanged between the host device 102 and the memory 108. Alternatively, the interconnect or memory bus 110 can propagate both the address stream 112 and the data stream 114 at least partially over the same physical wire or wires. As some examples, the interconnect 110 can include a front-side bus, a memory bus, an internal bus, peripheral control interface (PCI) bus, etc. If the interconnect or memory bus 110 includes a command bus or propagates a command stream, the host device 102 can also or instead propagate data over the command bus or command stream.

The processors 104 execute a program 116 and, through the memory controller 106, read from and write to the memory 108. Executing the program 116 configures the processors 104 and the memory controller 106 of the host device 102 to communicate data 122 in the address stream 112 and on the memory bus 110 that is shared with the memory 108. The processors 104 may include or may be the computer's: host processor, central processing unit (CPU), graphics processing unit (GPU), artificial intelligence (AI) processor (e.g., a neural-network accelerator), or other hardware processor or processing unit.

The memory 108 is illustrated as a memory for the computer 100; however, the memory 108 can be integrated within the host device 102 or separate from the computer 100 and/or can be of various types. For example, the memory 108 can include an integrated circuit memory, dynamic memory, random-access memory (e.g., DRAM, SRAM), or flash memory to name just a few. Any addressable memory having identifiable locations of physical storage can be used as the memory 108. Further, although the host device 102 and the memory device 108 are depicted as being discrete components, the host device 102, the memory device 108, and the interconnect 110 may alternatively be integrated on a single die (e.g., as an SoC).

A module referred to as the program 116, as well as any other module described herein, may be stored in a computer-readable media or other hardware components of the computer 100. Each module, including the program 116, represents a set of processor-executable instructions, including software instructions, firmware instructions, or a combination thereof.

Responsive to the processors 104 executing the instructions defining the program 116, the host device 102 is configured to communicate the data 122 in the address stream 112 of the memory bus 110, which is shared between at least the memory 108 and the host device 102. For example, as part of a conventional memory-write or read command issued during a first frame of memory traffic on the memory bus 110, the program 116 causes the processors 104 and the memory controller 106 to output addresses 118 in the address stream 112 and to output data 120 within the data stream 114. The data 120 may indicate what the memory 108 is to store at the addresses 118 included in the address stream 112, and alternatively, for a read, the data 120 may indicate what the memory 108 reads in the address specified in the address stream. The memory 108 executes the write or read command by storing the data 120 received on the data stream 114 in a storage location of the memory 108 that is defined by the addresses 118.

In some implementations, in a subsequent frame of traffic on the memory bus 110, which is described next, the program 116 directs the processors 104 and the memory controller 106 to output data 122 in the address stream 112. The memory 108 or (as later described) a logic analyzer, which is internal or external to the computer 100, is configured to determine the data 122 communicated through the address stream 112 between the memory 108 and the host device 102. The data 122 is not interpreted to be a memory address for a read or write command, which is the case for the addresses 118 and the data 120. Instead, the data 122 represents a payload of information, metadata in some cases, or a mailbox location through which information, such as metadata, is to be communicated.

In response to detecting the data 122, the memory 108 may use the data 112 to perform a function, such as a PIM operation. A hidden channel embedded within the address stream 112 therefore provides an additional communication path between the memory controller 106 of the host device 102 and the memory 108. When fed into a memory simulator or other platform used for processing the address stream 112, the data 122 may cause the memory simulator or other platform to output or display an indication of the data 122, for example, during playback and trace-analysis. An engineer or tester can consider the data 122 to aid in interpreting a trace of signaling on the memory bus 110 or to memory issues associated with portions of the program 116. A simulator or other processing platform, including the program 116, can use the data 122 to determine data or control dependencies between memory requests, which can enable more accurate simulation output.

The data 122 may include a program context indication, such as a thread identifier (TID) or a pointer to a longer thread identifier. The program 116 can inject the thread identifier into the hidden channel within the address stream 112 as the data 122. For example, the thread identifier categorizes prior memory requests involving the addresses 118 and the data 120, which appeared earlier in the trace. Alternatively, the thread identifier can precede the relevant memory requests in the address stream 112. As a function of the program 116, the program 116 can periodically direct the processors 104 to send the data 122. When implemented at an operating system level, an operating system of the computer 100 can direct the host device 102 to send the data 122 on each change in process-context or each thread-context switch. The data 122 may be associated with a first thread or a first CPU core of the processors 104 in an initial frame on the memory bus 110, and in a subsequent frame, the data 122 may originate from a different thread or a different CPU core of the processors 104. When the host device 102 includes a cache, the thread or CPU core of the processors 104 that triggers a write-back might not be the same thread or CPU core of the processors 104 that last accessed the data. In contrast, memory-reads are triggered by a most-recent read operation, prior to the transmission of the data 122. The ability to convey a thread or process identifier enables a simulator or other program to indicate through their respective outputs, requests from different threads being executed in parallel, without the simulator or other program needing to keep track of dependencies.

Including byte-loads and byte-stores (e.g., non-cacheable, input-output) issued by the program 116 can direct the processors 104 of the host device 102 to send the data 122 via the memory controller 106 to the memory 108 at a precise time or within a particular frame. Alternatively, an address may be written back (if necessary) and invalidated prior to reading the address representing data in order to generate an address on the bus 112. Memory fencing techniques may be used to accurately position the data 122 within a memory trace, relative to other memory accesses recorded in the memory trace. Operations issued within a memory fence are certain to be executed by the processors 104 and the memory controller 106 prior to operations issued outside the memory fence. The program 116 may include or be any instrumentation, software library, or other type of module configured to inject metadata in the address stream 112 as the data 122. Alternatively, hardware circuitry of the host device 102 may inject the data 122 into the address stream 112.

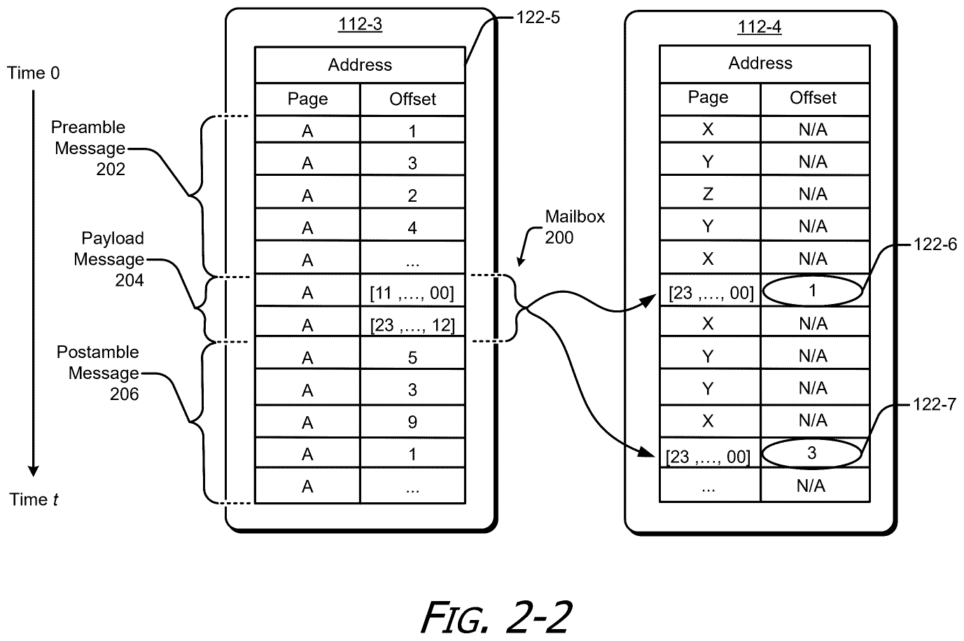

In operation, the program 116 may inject a thread identifier into the address stream 112 on the memory bus 110, which appears in the address trace being probed, whenever the program 116 switches to a new thread. The memory 108, other program, or trace analyzer that receives the thread identifier determines which thread executing on the processors 104 of the host device 102 is producing the addresses for memory operations that follow. The thread identifier, along with other types of data 122, are examples of context, which provides a richer trace because individual sections of the trace can be associated with different threads. This thread identifier or other data 122 may appear on the memory bus 110 before, after, or as part of a payload message, which is described with reference to FIGS. 2-1 and 2-2.

### Mailbox Communication and Messaging Protocol

FIGS. 2-1 and 2-2 illustrate aspects of communication within an address stream, in which a mailbox is referenced by data in the address stream. FIG. 2-1 illustrates mailbox communication, which involves the communicating program allocating memory for the mailbox upfront using repeated transmissions. FIG. 2-2 illustrates a messaging protocol, which utilizes preamble, payload, and/or postamble messages to convey data from one end of the address stream to the other. In the examples of FIGS. 2-1 and 2-2, time elapses in the downward direction from time 0 to time t.

By default, the memory 108 (of FIG. 1) treats bits of information in the address stream 112-1 as addresses 118 for a memory request. The processors 104 and the memory controller 106 of the host device 102 are configured to communicate addresses 118 in the address stream 112-1 shared with the memory 108. The memory 108 uses the addresses to read, write, or otherwise execute a memory operation with the memory 108.

In some implementations, the address stream 112-1 can adhere to a split-transaction protocol. The split-transaction protocol allows the memory controller 106 and the memory 108 to execute groups of load and store instructions in a non-atomic way, without the program 116 or the processors 104 having to manage their execution. Operating a memory with a split-transaction protocol can facilitate efficient memory accesses.

Turning first to FIG. 2-1, which illustrates an example mailbox 200 that is established in a portion of the memory 108 allocated in advance, before the program 116 embeds data 122-2, 122-3, or 122-4 in an address stream 112-2. The address streams 112-1 and 112-2 are examples of the address stream 112. The program 116 causes the computer 100 to allocate the mailbox 200 as a contiguous amount of storage at the memory 108. The mailbox 200 may be equal to a size of a page in memory, or multiple pages of memory to increase a size of the offset and thereby increase bandwidth or improve checksum performance. To establish the mailbox 200, the program 116 causes the host device 102 to send a repeating pattern (n cycles) of addresses in the address stream 112-1 within a window 208. The window 208 may be established as having a particular length of time (e.g., a time window) or having a particular quantity of address entries of the address stream 112-1. One address in each repeating pattern can represent a checksum for determining an order to the remaining (two in this example) addresses in the repeating pattern. The remaining addresses, when concatenated together in a particular order that satisfies the checksum, define the page or range of pages for the mailbox 200. Although the addresses for the two depicted cycles are illustrated as being temporally adjacent, the addresses may alternatively be separated by other addresses, including those with addresses for memory requests or those with data that are masquerading as addresses for memory requests.

In response to detecting n repetitions of two or more address entries with a corresponding checksum, within an allowed window 208 of addresses, and with little or no interspersed or spurious other addresses, the memory 108, a logic analyzer, or other recipient that detects the repeating pattern in the address stream 112-1 determines that mailbox 200 is dedicated to the program 116 for the duration of the program 116. This allows the program 116 to establish a private mailbox for application-specific data. This can be simpler than using a preamble, payload, and/or postamble message, which is described in FIG. 2-2, because a preamble or postamble recognition scheme can be avoided while still handling the address re-ordering by the host device 102 that can make a mailbox hard to decode.

As shown in FIG. 2-1, the recipient of the address stream 112-2 can interpret data 122-2, 122-3, and 122-4 based on subsequent memory requests that reference the mailbox 200. Because the mailbox 200 is contained within a privately allocated portion of the memory 108, which is owned by the program 116, there is not likely to be interfering, or unintended addressing to the mailbox 200 within the range of addresses allocated to the mailbox 200.

As an alternative to establishing the mailbox 200 with repeated transmissions, FIG. 2-2 shows how a messaging protocol can be used to indicate the location of the mailbox 200. In processing the address stream 112-3, which along with address stream 112-4 are examples of the address stream 112, a recipient can determine the mailbox 200 from having identified a preamble message 202, a postamble message 206, and/or a payload message 204 in-between. The address stream 112-3 propagates or carries data 122-5, which is an example of the data 122. The address stream 112-3 provides the mailbox 200, and the address stream 112-4, which occurs subsequently, references the mailbox 200 to communicate additional data 122-6 and 122-7, as further examples of the data 122.

In operation, the memory 108 determines that a current portion of the address stream 112-3 includes an indication of the data 122-1 as opposed to addresses. Responsive to determining that the current portion of the address stream 112-3 includes addresses 118 and does not include data embedded therewith, the memory 108 executes reads or writes to fulfill memory requests with the addresses 118 contained in the current portion of the address stream 112-1.

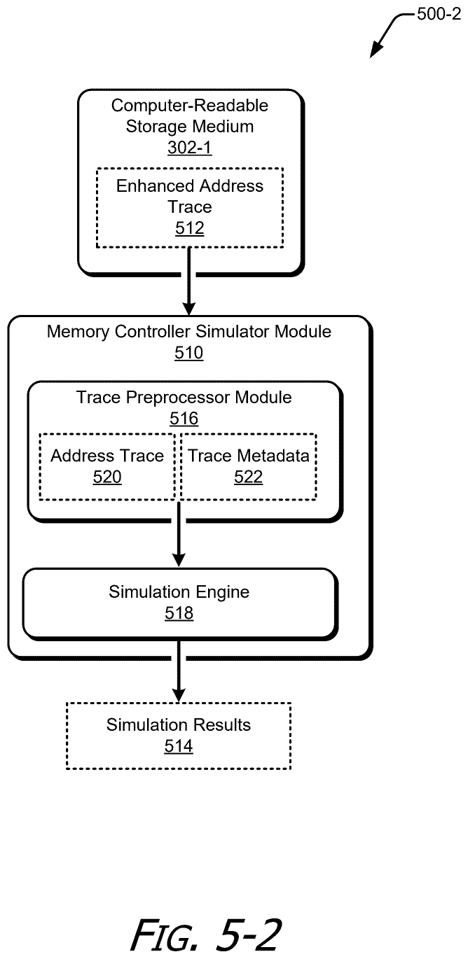

In contrast, when the indication of the data 122-1 appears in the address stream 112-3, the memory 108 interprets the address stream 112-3 differently than if it were the addresses 118. Based on the data 122-5 appearing in the address stream 112-3, the memory 108-1 can, in some cases, determine a context of a memory request or a command to perform rather than determining an address page or offset associated with a memory request. Alternatively, for a memory device that is used as a recipient of address requests in order to collect command and address traces, the memory device can operate on read and write requests in the usual manners. Further, the encoded addresses can be used for other purposes besides a memory device command as described herein. Responsive to determining that the current portion of the address stream 112-3 includes the data 122-5, the memory 108 can ignore the data 122-5. Alternatively, the memory 108 can extract the data 122-5 from the current portion of the address stream 112-3 to perform a command or save the data 122-5 for outputting as part of a testing scenario, which is described with reference to FIG. 5. Although some of the description herein refers to the memory 108 or 108-1, as the device processing an address stream 112 or taking actions based on detected data 122 during operation or testing, these descriptions may also or instead apply to acts performed by a computing device, logic analyzer, or test equipment that is processing the address stream (e.g., offline after a test has been concluded).

To convey the data 122-5 within the address stream 112-3, the processors 104, acting through the memory controller 106, communicate a payload message 204, and optionally, a preamble message 202 and/or a postamble message 206, in any order. If the preamble message 202 or the postamble messages 206 is output, the host device 102 outputs the preamble message 202 before communicating the payload message 204, which typically precedes the postamble message 206. The memory controller 106 can, however, reorder the messages 202, 204, 206 within the address stream 112-3 as part of a scheme to issue memory requests in an order that efficiently accesses different memories cards, banks, or modules. Thus, the memory bus 110 may convey to the memory 108 the payload message 204 before or after transmitting either of the optional preamble or postamble messages 202 and 206. The memory 108 can nonetheless identify the preamble message 202, the payload message 204, and the postamble message 206, no matter the order of appearance in the address stream 112-3. Responsive to identifying the preamble message 202, the memory 108 interprets the payload message 204 as containing or being at least part of the data 122-5. The memory 108 determines an end to the data 122-5 in response to identifying the postamble message 206.

The host device 102 indicates a beginning or head of the payload message 204 by outputting the preamble message 202. The preamble message 202 appears in the address stream 112-3 at time 0 and alerts the memory 108 to the start of the payload message 204.

To determine that the address stream 112-3 includes the payload message 204, the memory 108 may look for the preamble message 202. The preamble message 202 is a repeating sequence of addresses across multiple address strides. The host device 102 communicates (e.g., places or drives) the addresses of the preamble message 202 onto the memory bus 110 repeatedly (e.g., hundreds of times). The memory 108, or a logic analyzer of the computer 100 or automated test equipment (ATE) for memory simulation scenarios that are performed offline, identifies the preamble message 202 in response to recognizing the repeating sequence of addresses within some sliding window of addresses (not shown in FIG. 2-2). In some cases, the pattern of addresses in the preamble message 202 is derived from deltas between addresses, rather than absolute values of the addresses themselves. Also referred to as inter-address-deltas, each address-delta is a difference between two addresses. In summary, the data 122-5 is transferred within the address stream 112-3 as a predetermined pattern of addresses or inter-address-deltas that the memory 108, or the logic analyzer, is programmed to recognize. In some examples, the predetermined pattern is a statistical distribution of addresses, which are interpreted together as the preamble message 202.

In example operations, the memory 108 is configured to determine that the address stream 112-3 includes the preamble message 202 by identifying a pattern of offsets of addresses in the address stream. In FIG. 2-2, the pattern of offsets in the preamble message 202 includes the offsets [1, 3, 2, 4]. The memory 108 recognizes the preamble message 202 in response to identifying such a pattern of offsets in the address stream 112-3. Responsive to determining that the address stream 112-1 includes the preamble message 202, the memory 108 detects or determines the presence of the payload message 204.

To improve reliability in communicating the data 122-5 within the address stream 112-3, the pattern of offsets in the preamble message 202 may encode a pattern of deltas that indicate the preamble message 202. Each delta in the pattern of deltas is an inter-address difference or delta between pairs of the offsets in the address stream 112-3. In FIG. 2-2, the pattern of deltas in the preamble message 202 includes [+2, −1, +2]. The memory 108 may recognize the preamble message 202 in response to identifying the pattern of deltas.

During a subsequent communication of data 122-3 in the address stream 112-3, the memory 108 may identify the same pattern of deltas [+2, −1, +2] based on the same or a different pattern of offsets previously included in the preamble message 202. For example, the memory 108 can recognize the preamble message 202 in a subsequent portion of the address stream 112-3 that the pairs of offsets in the subsequent portion of the address stream 112-3 are the same or different than the pairs of offsets [1, 3, 2, 4] in a previous preamble message 202. If different from previous pairs of offsets, the pairs of offsets included in the preamble message 202 can again encode a pattern of deltas corresponding to [+2, −1, +2] to indicate the beginning of the payload message 204.

To compensate for an unknown reordering on the memory bus 110, which may be performed by the memory controller 106, the memory 108 may identify a particular ratio of offsets or deltas between pairs of offsets in the preamble message 202. For example, a pattern of deltas corresponding to [+2, +2, −1] may be deemed the same as the pattern of deltas including [+2, −1, +2] within a window of addresses of a given size. Likewise, rather than deltas, a particular ratio of offsets can be used to convey the preamble message 202. For example, the memory 108 may identify an equal quantity or distribution of offsets that correspond to 1, 3, 2, and 4.

The memory 108 may seek to identify hundreds of occurrences of the offsets to identify a single preamble message 202. For example, the computer 100 or operating system thereof has a four-kilobyte address range in each page of memory. The preamble message 202 includes absolute offsets (e.g., [1, 3, 2, 4]) within the page “A”. The memory 108 may recognize the preamble message 202 in response to identifying the absolute offsets within the page “A” or an equal quantity of each of the absolute offsets within a time window of the address stream 112-3. The memory 108 seeks a high density of addresses on the memory bus 110 that pertain to same memory page. For instance, a relevant high density of addresses reference a single page “A,” and each address has one of the absolute offsets found in the preamble message 202. In response to identifying a sufficient quantity of each of the absolute offsets to satisfy a pattern of the preamble message 202, the memory 108 determines that the data 122-5 is being communicated on the memory bus 110 in the address stream 112-3.

The memory 108 may not identify the preamble message 202 with one hundred percent certainty, but the memory 108 likely detects the preamble message 202 with near (e.g., ninety-nine percent) certainty. The memory 108 may maintain a list of every page addressed within the sliding time window mentioned above. The memory 108 identifies the preamble message 202 in response to identifying a page with a high-reference-rate and a majority of absolute offsets that match the pattern of the preamble message 202.

Before time t, and after communicating the payload message 204 within the address stream 112-3, the processors 104 cause the memory controller 106 to communicate the postamble message 206 on the memory bus 110 as part of the address stream 112-3. The processors 104 output the postamble message 206 to indicate an ending of the payload message 204 and an end to the communication of the data 122-3 for this incidence.

The host device 102 communicates the postamble message 206 in the address stream 112-3 similarly to how the host device 102 causes the memory controller 106 to communicate the preamble message 202. For example, the processors 104 cause the memory controller 106 to output the postamble message 206 as a series of consecutive addresses to a common page in the memory 108, which series includes a particular pattern of absolute offsets or deltas in the address stream 112-3. Responsive to determining that the address stream 112-3 includes the postamble message 206, the memory 108 determines an end to the communication of the data 122-5.

In response to determining the postamble message 206, the memory 108 determines the data 122-5 based on a content of offsets that define the payload message 204, which appear before the postamble message 206 in the address stream 112-3. Between time zero and time t, the address stream 112-3 includes a time-ordered sequence of addresses within a single page “A” within the memory 108. The addresses of the data 122-5 may be transmitted by the host device 102 in the order received by the memory controller 106 from the processors 104. Alternatively, the memory controller 106 may reorder addresses of the address stream 112-3 or scramble addresses transmitted on the memory bus 110 at this time after, for example, what may be relatively long periods where the addresses appear in order. The memory 108 can account for the reordering of addresses that make up data when interpreting the addresses based on a sequence indication, a checksum, and so forth.

The memory 108 determines that the address stream 112-3 includes the postamble message 206 by identifying a corresponding pattern of offsets. In FIG. 2-2, the pattern of offsets in the postamble message 206 includes [5, 3, 9, 1]. The memory 108 is configured to recognize the postamble message 206 in response to identifying this pattern of offsets. As discussed above in relation to the pattern of offsets in the preamble message 202, the pattern of offsets in the postamble message 206 may also encode a pattern of deltas. Each delta in the pattern of deltas is a difference between pairs of the offsets within the postamble message 206. To improve reliability in communicating the data 122-5 within the address stream 112-3, the memory 108 may recognize the postamble message 206 in response to identifying multiple addresses as including another pattern of deltas in the address stream 112-3. For example, in FIG. 2-2, the other pattern of deltas in the postamble message 206 includes [−2, +6, −8].

In some cases, the payload message 204 of the data 122-5 includes a portion of the address stream 112-3 received after the preamble message 202 and before the postamble message 206. The payload message 204 encodes the data 122-5 within address bits that make up page offsets of addresses to a page “A” in the memory 108, which is the same page “A” in the addresses of the preamble and postamble messages 202 and 206. The data 122-5 may therefore correspond to at least the actual bit-content of the offset portion(s) of the payload message 204. In some examples, the data 122-5 includes a mailbox 200 that indicates a location that can be referenced when future data 122 is communicated, which is described with reference to the address stream 112-4.

Within the payload message 204, the host device 102 may communicate a mailbox location, which can include a page in the memory 108 that is referenced to efficiently communicate future data 122. For example, the mailbox 200 can correspond to a page address of the memory 108 that is referenced to communicate data 122-6 and 122-7. Thus, the mailbox 200 can also serve to indicate additional data, such as the data 122-6 or 122-7, to the memory 108 or a trace analyzer. The host device 102 communicates the mailbox location as address bits transmitted within the payload message 204. In this way, the payload message 204 can include actual, data 122-1 and/or a reference to a location of future data 122-6 or 122-7 to be communicated to the memory 108.

Based on the parts of the address stream 112-4 received after the preamble message 202, the memory 108 identifies a mailbox location of the mailbox 200. Based on the payload message 204, the memory 108 interprets the offsets as a mailbox location indicating a page of memory 108 that identifies when data 122-6 and 122-7 is being communicated. The offset bits numbered [11, . . . 0] and [23, . . . 12] that appear in the payload message 204 are interpreted as a reference to establish the mailbox 200, rather than as an addressable offset for a memory request. In the example of FIG. 2-2, the memory 108 determines the data 122-6 and 122-7 to include “1” and “3,” respectively, in the address stream 112-4.

Between time zero and time t, the address stream 112-3 includes a time-ordered sequence of addresses within a single page “A” that are sent to the memory 108. For ease of description, the addresses of the data 122-5 are transmitted by the memory controller 106 in the address stream 112-3 in the order received from the processors 104. As described in relation to the other drawings, the address stream 112-3 may include reordered or scrambled addresses during transmission on the memory bus 110 after what may be long periods where the addresses appear in order. As described below, the memory 108 can account for the reordering of addresses that make up data when interpreting the addresses using, for instance, an order-dependent checksum.

While the data 122-5 may appear as regular addresses including page and offset values, the page and offset values of the data 122-5 convey a message for the memory 108. A preamble message 202 appears initially on the memory bus 110 at time zero. The preamble message 202 precedes a payload message 204. The preamble message 202 and the payload message 204 are followed by a postamble message 206, which completes its transmission on the memory bus at time t. The moment that the preamble message 202 ceases, the memory 108 or logic analyzer may interpret addresses on the memory bus 110 as payload information. In the example of FIG. 2-2, the payload message 204 takes two memory cycles.

Rather than merely sending the data 122-5 as the payload message 204, the host device 102 can send the payload message 204 to initialize the mailbox 200 to establish how future data 122-6 and 122-7 will be indicated. The addresses in the payload message 204 encode data or a pointer to data for the mailbox 200. In the example of FIG. 2-2, the payload message 204 includes two address portions numbered [11, . . . ,0] and [23, . . . ,12]. When combined (e.g., concatenated), the two portions establish a memory page for the mailbox 200. If the memory page corresponds to page “P” of the memory 108, the data 122-6 and 122-7 are communicated within address offset bits of the page “P” mailbox 200. The data bits directed to the mailbox 200 may be ignored in terms of standard memory requests. On the host side, the processors 104 allocate the page “P” of the memory 108 to the program 116 for exclusive use by the program 116 to communicate the data 122-6 and 122-7, and potentially additional data. After initializing the mailbox 200, a subsequent address along the address stream 122 to the page “P” is a reference to a location of the memory 108 that is indicative that data is being communicated and may be interpreted or stored accordingly.

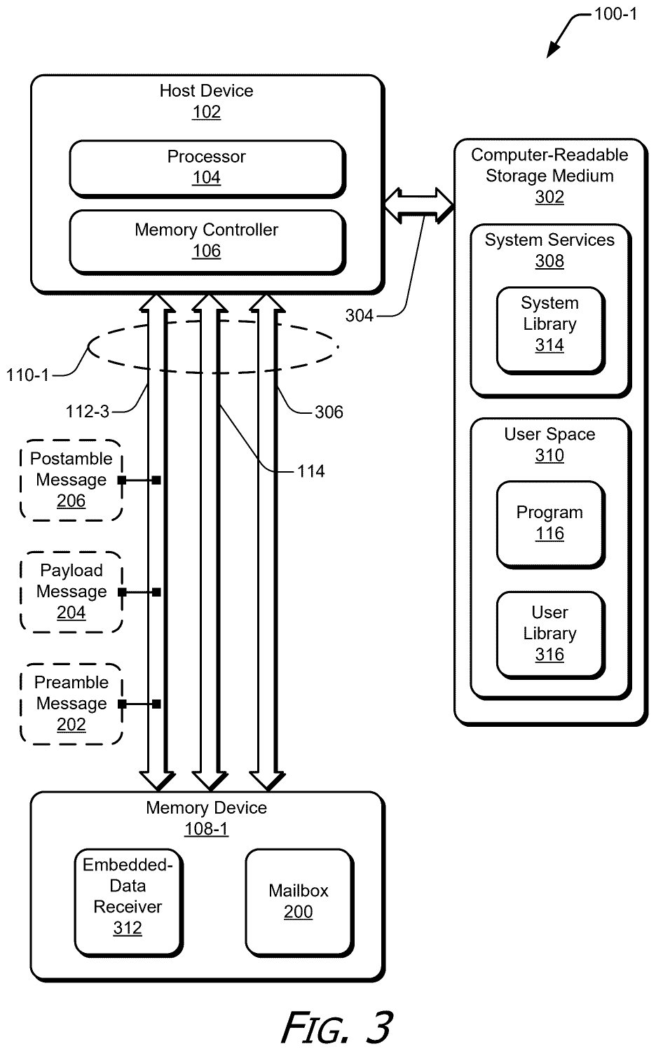

FIG. 3 illustrates an example computer 100-1 configured to send data embedded in an address stream. The computer 100-1 is only one example of the computer 100, and it is shown in greater detail. The computer 100-1 includes a computer-readable storage medium 302, which may be a non-transitory computer-readable storage medium. The host device 102 exchanges information with the computer-readable storage medium 302 over an interconnect 304. The computer-readable storage medium 302 may be realized at least partially using a memory device 108-1 and/or part of the host device 102, or the computer-readable storage medium 302 may be physically separate from the host device 102.

The computer-readable storage medium 302 includes multiple groups of data: one group is labeled user space 310, and the other group is labeled system services 308. The system services 308 provide applications that are accessible from the user space 310 including access to a variety of services and functions, such as a system library module 314 (also referred to simply as “a system library 314”). For example, the program 116, which is shown in FIG. 3 as being maintained in the user space 310, can call on a system function or a system task from the system library 314 to perform an operation on behalf of the program 116. The user space 310 may include a user library 316. The user library 316 may be customizable by a user of the computer 100-1 and provides applications executing from within the user space 310 with access to additional services and functions than those provided by the system library 314. The user library 316 or the system library 314 may include functions that, when called, enable the program 116 to send embedded data within the address stream 112.

The computer 100-1 also includes the host device 102, including the one or more processors 104 and the at least one memory controller 106. A memory bus 110-1, which is an example of the memory bus 110, propagates the address stream 112-3 and the data stream 114 between the memory controller 106 of the host device 102 and the memory 108-1. The address stream 112-3 carries, for example, the preamble message 202, the payload message 204, and the postamble message 206 that are sent from the host device 102. The memory bus 110-1 also includes one or more control lines 306, which carry control signals back and forth between the host device 102 and the memory device 108-1.

The memory 108-1 is an example of the memory 108. Included in the memory 108-1 is an optional embedded-data receiver module 312. In practice, the memory device 108 may be used, which does not necessarily include any hardware or software modifications, such as the inclusion of the embedded-data receiver module 312.

The embedded-data receiver module 312 determines that the address stream 112-3 includes addresses or data. In response to identifying data by, for example, detecting the preamble message 202, the embedded-data receiver module 312 configures the memory 108-1 to act on the data rather than process the address stream 112-3 as if it contained the kind of address typically observed on the memory bus 110-1 during a read, write, or other memory request.

The embedded-data receiver module 312 configures the memory 108-1 to identify, based on the payload message 204, the mailbox 200 where a dedicated page in the memory 108-1 is reserved to designate data. For some types of data, multiple mailbox locations may be used to transmit different types of data from the host device 102 to the memory 108-1. In such cases, the embedded-data receiver module 312 can determine, based on the payload message 204, multiple portions of the data that are associated with different mailbox locations. Additionally or alternatively, the embedded-data receiver module 312 can determine how many bits are associated with a page address portion and how many bits are associated with an offset address portion. Based on this information, the embedded-data receiver module 312 can interpret different sizes of data appropriately or concatenate multiple portions of data together. Thus, the host device 102 and the memory 108-1 can exchange data of varying sizes or amounts.

The program 116 can call on a function maintained by the system library 314 or the user library 316 to enable the program 116 to send data embedded in the address stream 112-3. In response to the function call, the processors 104 execute the function to request that the memory controller 106 allocate a page of the memory 108-1 to the program 116 for maintaining the mailbox 200. The program 116 interfaces with the libraries 314 or 316 to communicate the data using one or more mailbox locations.

As part of an initialization, the libraries 314 and 316 cause the processors 104 to communicate the one or more mailbox locations within the payload message 204. For example, the offsets within the payload message 204 can point to a location of the mailbox 200, such as by providing an address of a memory page for the mailbox 200. The program 116 outputs additional data by reading or writing at different times to the page address of the mailbox location of the memory 108-1 that is allocated to the program 116. For example, the libraries 314 or 316 can cause the processors 104 to output other data as offsets to the mailbox page within a subsequent payload message appearing on the address stream 112-3.

As one example, the program 116 can communicate a thread identifier associated with the program 116 with reference to a location of the mailbox 200. The thread identifier can be relatively long and therefore span multiple address offsets or address deliveries via the mailbox to communicate the entire thread identifier. The program 116 can output an indication of the mailbox page via which the data is communicated in a function call to the system library 314. For example, the mailbox location may correspond to a 24-bit address of the page of the memory 108-1 allocated for the mailbox 200. The program 116 can also provide the data to the system library 314.

In response to the function call by the program 116, the system library 314 generates the preamble message 202. By directing the processors 104 to output the preamble message 202, the system library 314 alerts the embedded-data receiver module 312 of the memory 108-1 to monitor the address stream 112-3 for the payload message 204. The embedded-data receiver module 312 determines that the preamble message 202 includes a sequence or pattern of offsets inserted to indicate a transmission of data. For example, the preamble message 202 may include a particular distribution of offsets in a long sequence of addresses, which the embedded-data receiver module 312 is programmed to identify.

Based on the information received from the program 116 about the mailbox location via which the data is to be communicated, the system library 314 generates the payload message 204. The payload message 204 may include, with reference to the location of the mailbox 200, the thread identifier or other data to be communicated. The data can be inserted as the offsets in a series of addresses appearing in the address stream 112-3. The common page identifier in the series of addresses that are included in the payload message 204 indicate to the embedded-data receiver module 312 at the memory 108-1 that data is being communicated via the mailbox 200.

The embedded-data receiver module 312 obtains the data identified by the mailbox 200 and included in multiple addresses of the address stream 112-3 as the payload message 204. By concatenating multiple portions of the data together, the embedded-data receiver module 312 determines the thread identifier of the program 116. Other types of information, including other kinds of program-execution context data, may alternatively be communicated over the address stream 112-3 via the established mailbox 200. Although some of the description herein refers to the embedded-data receiver module 312 processing an address stream 112-3 or taking actions based on detected data during operation or testing, these descriptions may also or instead apply to acts performed by a logic analyzer or test equipment that is processing the address stream (e.g., offline after a test has been concluded).

Using the established mailbox 200 allows larger amounts of data to be efficiently shared over the address stream 112-3 because the preamble message 202 is not needed for each piece of information being communicated. Using a mailbox 200, however, is not required for communicating data over the address stream 112-3. Furthermore, using the messaging protocol is not required to transmit data or an indication of data, within the address stream 112-3. Rather, the mailbox 200 can be allocated to a page in memory by the host device 102, such than whenever a recipient of the address stream 112-3 (e.g., the memory 108-1) identifies the page where the mailbox 200 is allocated, the recipient decodes the address referencing the page to be an offset to data in the mailbox 200.

As described above, in some examples the payload message 204 contains data that is informative of current processing characteristics or dependencies or that instructs the memory 108-1 to perform some function. This informative data is provided as an offset address instead of providing a mailbox location as shown in the address streams of FIGS. 2-1 and 2-2. In other words, the offsets within the payload message 204 may represent individual portions of data. When concatenated together by the embedded-data receiver module 312, the individual portions enable the thread identifier or other context data of the program 116 to be determinable directly from a memory trace of the memory bus 110-1.

### Checksum Usage for Detection of Data in Address Streams

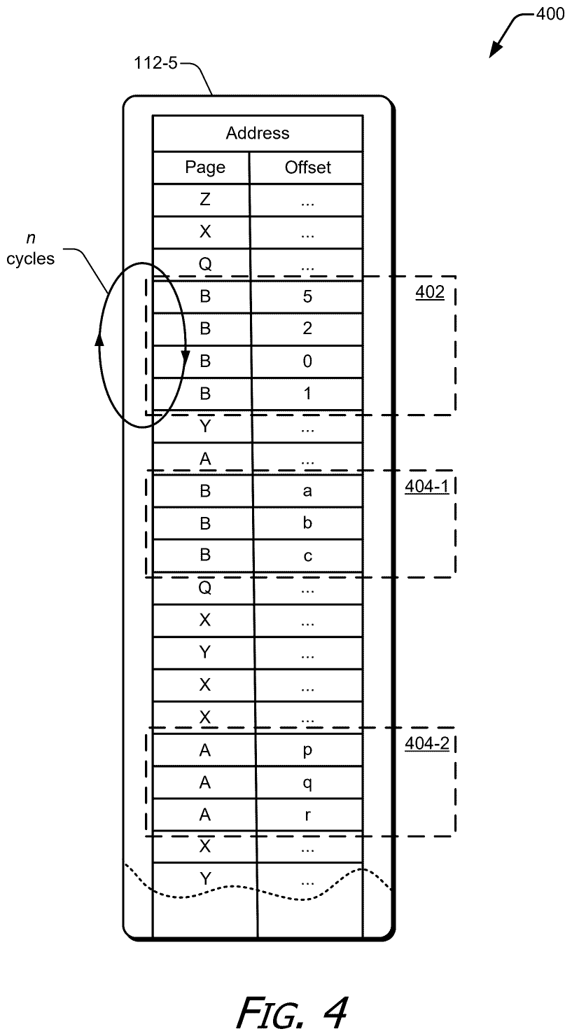

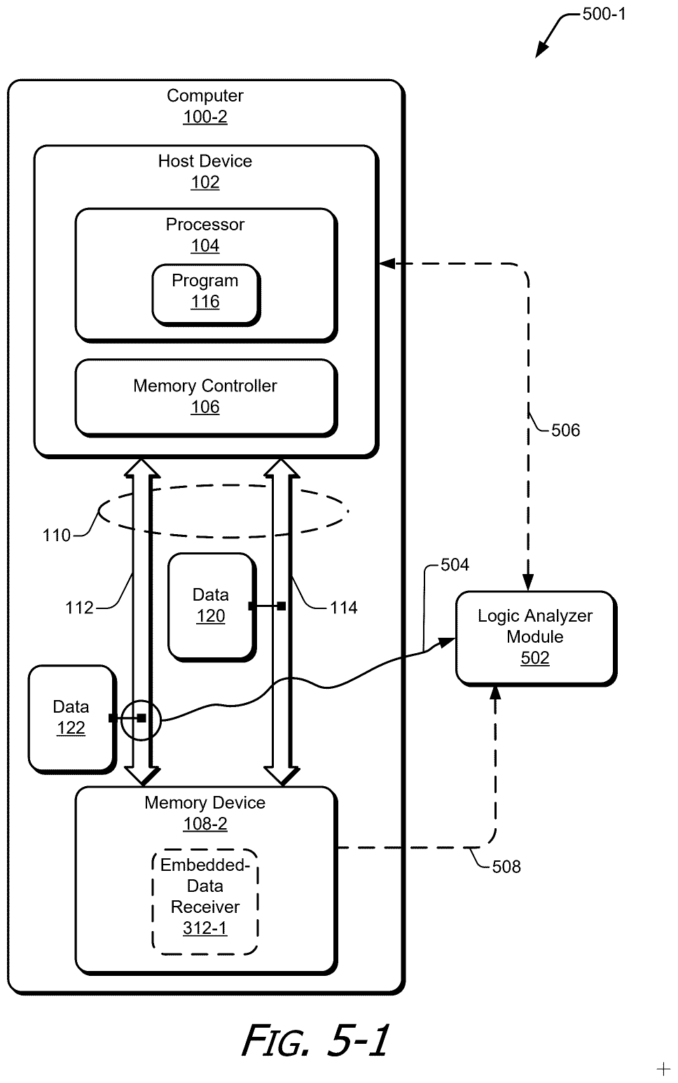

FIG. 4 illustrates an example detection scheme 400 with an address stream 112-5 that supports detection of transmissions of data. When the program 116 or an operating system of the computer 100 wants to communicate embedded data via an address portion of the memory bus 110, a routine in the library 314 or 316 can direct the host device 102 to inject a preamble message 402 into the address stream 112-5. The preamble message 402, responsive to being identified by the embedded-data receiver module 312 of the memory 108-1, can presage transmissions of additional data using the messaging protocol described herein. This messaging protocol, which uses a checksum with each transmission of data, can obviate the use of a preamble message 402 for each such transmission.

The preamble message 402 in the address stream 112-5 includes a sequence of four addresses to page “B” with offsets [5, 2, 0, 1]. The indication of the presence of data by the preamble message 402 can be based on absolute offsets [5, 2, 0, 1] or on a series of inter-address deltas [−3, −2, +1]. The preamble message 402 can be repeated in the address stream for n cycles, with n being any positive integer. Repeating the sequence of offsets tens, hundreds, or thousands of times improves the likelihood that the embedded-data receiver module 312 will identify the preamble message 402. Accurate identification can prevent erroneous positive or negative detection of data (e.g., erroneous positive detection of data can occur when the processors 104 are in-fact communicating physical addresses for a memory request).

In controlling the memory bus 110, the memory controller 106 can rearrange the order in which the addresses appear in the address stream 112-5. Thus, the order of the offsets or inter-address deltas may be flexible in accordance with some described implementations.

Instead of identifying a particular sequence of offsets, the embedded-data receiver module 312 can identify the preamble message 402 by identifying a particular distribution of offsets to a single page in a sliding window of time or a given quantity of addresses. For instance, the embedded-data receiver module 312 identifies the preamble message 402 in response to noticing hundreds of addresses to the page “B” with the offsets “5,” “2,” . . . , and so forth. For each of the different absolute offsets or inter-address deltas observed in the address stream 112-5 during the sliding window of time, the embedded-data receiver module 312 keeps a count.

In response to determining that the counts of each of the different absolute offsets or inter-address deltas are equal during the sliding time window, the embedded-data receiver module 312 records the page “B” referenced in the preamble message 402 as the mailbox 200 (of FIG. 2). The module also begins to monitor for a payload message 404, which references the same page address “B” indicated in the preamble message 402. On the other hand, responsive to determining that the distribution of offsets does not match an expected distribution of offsets of a preamble message 402, the embedded-data receiver module 312 ignores the addresses in the address stream 112-3 because the addresses do not include embedded data.

Sending the preamble message 402 to start communicating data in this way can improve reliability and reduce noise in the address stream 112-5. This can be helpful because the other contents of the address stream 112-5 might interrupt a sequence of related addresses used for communicating embedded data. For the embedded-data receiver module 312, any noise within the address stream 112-5 corresponds to addresses for legitimate memory requests, as opposed to a transmission of data. The addresses that convey data are identified, and possibly recorded or otherwise used, by the embedded-data-receiver module 312, while the addresses for memory requests are not. In some cases, in response to determining the mailbox is, or corresponds to, page “B,” the embedded-data receiver module 312 recognizes that this means the entire page “B” is exclusive to the program 116 for communicating data. There will likely be little-to-no noise in the mailbox page, so any addresses that are directed to the page “B”are determined by the embedded-data receiver module 312 to be transmissions of data.

Having identified the page “B” of the memory 108-1 as the mailbox 200 that the computer 100-1 allocated to the program 116, the embedded-data receiver module 312 determines that any additional addresses in the address stream 112-3 reference the page “B.” Once the mailbox page “B” is established, the library 314 or 316 directs the host device 102 to output a payload message 404-1, including offsets [a, b, c]. The program 116, acting through the library 314 or 316, can therefore encode packets of data as offsets within the mailbox page “B.”

The address stream 112-5 can transmit a payload message of any size, and the embedded-data receiver module 312, likewise, can receive and interpret a payload message no matter the size. Initially, the library 314 or 316 receives a request from the program 116 to transmit data. Within the request, the program 116 can share the size of the data with the library 314 or 316. In other examples, the library 314 or 316 can determine a quantity of addresses required to output the data by determining how many bits the data occupies. Based on this quantity of bits or size of the request and the quantity of bits per offset, the library 314 or 316 determines a number of addresses that will be used in the address stream 112-5 to send all the data in a single payload message 404. For example, the library 314 or 316 determines a total quantity of bits required for the payload message 404-1 to include the data [a, b, c]. By dividing this total quantity of bits by the data capacity of each address (e.g., the offset size in bits), the library 314 or 316 identifies a quantity of addresses for sending the data [a, b, c] as the single payload message 404-1.

To enable the decoding or detecting of data when received by the embedded-data receiver module 312 as part of the address stream 112-5, the library 314 or 316 can provide a checksum with transmissions of the data. A checksum provides a value that is derived from core data and can therefore link the core data to the checksum, and vice versa. An example of a checksum is a cyclic redundancy check (CRC) code. The library 314 or 316 can implement a CRC code scheme by sending a CRC checksum (also sometimes referred to as a “CRC value” or more simply as a “CRC”) for the data, which can be part of the payload message 404-1. For example, only two offsets [a, b] of the three offsets in the payload message 404-1 include the data, while the third offset [c] is the CRC checksum for a particular combination of the two other offsets in the data.

The library 314 or 316 calculates a quantity of addresses to send the data, and then calculates the CRC checksum over the offsets within those addresses. Including the CRC checksum as an offset within an additional address enables the embedded-data receiver module 312 to detect which addresses make up the payload message 404-1. In addition, the CRC checksum enables the embedded-data receiver module 312 to identify the CRC and piece the payload message 404-1 together in a correct order, even if the memory controller 106 rearranges the pieces of the payload message 404-1 and issues them over the memory bus 110 in a different order or as an unordered group.

In the illustrated example, over a sliding window of time, the address stream 112-5 includes the payload message 404-1. The payload message 404-1 is directed to the mailbox page “B” and includes three addresses with the offsets [a, b, c]. Although three offsets appear in the address stream 112-5, only two of the offsets are payload data, and the third is the CRC checksum. The embedded-data receiver module 312 may be unaware of which of the three offsets is the CRC checksum and a correct order of the payload data.

To determine which offset is the CRC checksum, the embedded-data receiver module 312 considers all the offsets in the payload message 404-1, which is identified by the address page “B,” combined (e.g., concatenated) in different permutations until a combination of all but one offset equals the CRC checksum of the remaining offset. For the offsets [a, b, c], the different combinations of offsets include abc, acb, bac, bca, cab, and cba. With a high probability, only one of the different combinations will pass a CRC check. For instance, “a+b” may produce a checksum “c.” The embedded-data receiver module 312 determines the combination that correctly specifies a CRC checksum computed for the other offsets received during the sliding window. The CRC check will fail if bits are in a different position from which the bits were encoded and output to the address stream 112-5. By considering each of the different combinations until the correct sequence of two address offsets results in a checksum indicated by the third offset, the embedded-data receiver module 312 can decode the data from the address stream 112-5 using the CRC checksum. Although a CRC checksum is used by way of example, other checksums that verify data payload, with or without order confirmation, can be used instead.

When the embedded-data receiver module 312 determines a combination of offsets that reference the mailbox page “B” and that pass the CRC checksum, the embedded-data receiver module 312 can isolate the offsets for the data and discard the offset containing the CRC checksum. The isolated offsets can then be saved or used to perform some function. If the embedded-data receiver module 312 fails to identify the CRC checksum in an identified payload message 404, the embedded-data receiver module 312 may output an alert or notification that the CRC checksum failed. For example, the embedded-data receiver module 312 can inject a failure code in a trace of the memory bus 110 in response to determining that no combination of offsets within a payload message 404-2 produce a CRC checksum that is included in the message identified by a different page address “A.”

Although not shown in FIG. 4 with a preamble message, the embedded-data receiver module 312 may have determined that the page address “A” of the memory 108-1 corresponds to the mailbox 200. In trying to determine the CRC checksum for the payload message 404-2, the embedded-data receiver module 312 may fail to identify a permutation of offsets [p, q, r] from the payload message 404-2 that satisfy the CRC checksum included in one of the other offsets. During subsequent analysis of the trace, the failure code that appears on the address stream 112-3 indicates where the CRC checksum failed, to aid in debugging the failure.

An advantage of this checksum technique is that it does not matter in which order the individual addresses to a mailbox appear because (except in very rare circumstances) the CRC check will only pass with a single correct combination. When computing or applying a CRC checksum, the order matters. If the offsets are analyzed in a different order from the one used to produce the CRC checksum, the CRC checksum will not be validated. The CRC checksum entails a specific order to the bits corresponding to the CRC, so if the ones and zeroes are in a different order, the CRC check fails.

The CRC can be computed or established by the library 314 or 316; however, attributes of the CRC checksum or a scheme implementing CRC do not need to be established up-front. The CRC can be any size, and the library 314 or 316 may communicate the size of the CRC checksum within the offsets of the preamble message 402 or a previous payload message 204 (e.g., of FIG. 2). These types of initializations can set up or communicates the size or type of the checksum that is to be used. Although it can be changed at runtime (e.g., through another preamble message), if the embedded-data receiver module 312 knows the number of bits for a CRC checksum before calculating the different combinations of offsets, the search for the correct combination of offsets can consume fewer processing resources or be completed more quickly.

The library 314 or 316 can additionally or alternatively communicate how many addresses form a group that includes both a checksum and the associated payload data to facilitate analysis at a memory device. In some of the example implementations described above, the checksum approach to detecting data is performed in conjunction with a mailbox page. For instance, the payload message 404-1 is depicted as using the page “B” as a mailbox. These implementations facilitate identifying those addresses that should be analyzed for potentially matching a checksum. However, these implementations also entail sending a preamble message 402, which can be relatively lengthy. Thus, in other example implementations, the payload message 404-1 can be sent without first establishing a mailbox. These implementations that omit a mailbox avoid the overhead of the preamble message 402 with an added cost for decoding the address stream 112-5 and detecting a set of related addresses using a checksum. Further, although some of the description herein refers to the embedded-data receiver module 312 processing an address stream 112-5 or taking actions based on detected data during operation or testing, these descriptions may also or instead apply to acts performed by a computing device, logic analyzer, or test equipment that is processing the address stream (e.g., offline after a test has been concluded).

### Testing Environment

FIG. 5-1 illustrates additional an example environment 500-1 in which various techniques and devices described in this document can operate to perform a memory test. The environment 500-1 includes a computer 100-2, which is an example of the computer 100-1. The computer 100-2 includes the host device 102 communicatively coupled with a memory device 108-2, which is an example of the memory device 108-1. The computer 100-2 is also communicatively coupled to a logic analyzer module 502, for example, via one or more probes 504 directly-coupled to the memory bus 110, via an interconnect 506 connected to the host device 102, or using an interconnect 508 coupled to the memory device 108-1. The logic analyzer module 502 may be an internal component of the computer 100-2 or even the memory 108-2 within the computer 100-2. In other examples, the logic analyzer module 502 is implemented external to the computer 100-2, such as by being part of ATE, and is configured to record a trace of the memory bus 110, such as a command and address bus portion thereof (not separately shown).

The logic analyzer module 502 determines the data 122 embedded within the address stream 112, directly from the address stream 112 or indirectly. The data 122 is directly determined from signals obtained via the one or more probes 504. To indirectly determine the data 122, other signals or information is used, specifically information or signals obtained from the host device 102 or the memory 108-2 over the interconnects 506 or 508. For example, an optional embedded-data-receiver module 312-1, which is an example of the embedded-data-receiver module 312, may determine the data 122 embedded within the address stream 112 and output the data 122. Either by directly or indirectly determining the data 122 embedded in the address stream 112, the logic analyzer module 502 uses the data 122 to tag or otherwise enhance a memory trace generated from other information appearing on the memory bus 110.

No matter the source of input signals, the logic analyzer module 502 can compile the signals received from the one or more probes 504, the interconnect 506, and the interconnect 508 into an enhanced memory trace that can be analyzed concurrently with traffic that appears on the memory bus 110, or offline. The logic analyzer module 502 may output the enhanced memory trace to a data file, the program 116, or another system for consideration by a test and evaluation group, for example, using the interconnect 506. This output from the logic analyzer module 502 may drive a user interface of the program 116 or a different application from which a user of the computer 100-2 can analyze operations associated with the host-device-to-memory-device interface, including the memory bus 110 of the computer 100-2.

The embedded-data receiver module 312-1 may output different information to the logic analyzer module 502 than the information the embedded-data receiver module 312-1 collects from the address stream 112. For example, the data 122, including a CRC checksum, may appear on the memory bus 110 as part of the address stream 112. In response to determining the CRC checksum and verifying the accuracy of the data 122, the embedded-data receiver module 312-1 may output a version of the data 122—the interconnect 508, except for excluding the CRC checksum from the data 122, originally. In some cases, the embedded-data receiver module 312-1 uses the data 122 without passing it on to the logic analyzer module 502. In this way, the communication of the data 122 can be transparent to the logic analyzer module 502.

### Simulation Environment

Turning to FIG. 5-2, illustrated is an example environment 500-2 in which various techniques and devices described in this document can operate to simulate a memory using results generated from a memory test. The environment 500-2 represents part of a simulator computing system and includes a memory controller simulator module 510, which when executed on a processor (not shown) configures the processor to output simulation results 514 based on an enhanced address trace 512, which includes data embedded in an address stream.

The memory controller simulator module 510 is communicatively coupled with a computer-readable storage medium 302-1, which is an example of the computer-readable storage medium 302. The logic analyzer module 502, for example, stores the enhanced address trace 512 based on information collected from at least one of the probes 504, the interconnect 506, or the interconnect 508. The computer-readable storage medium 302-1 may further store simulation results, control dependencies, or other address trace data or metadata.

The memory controller simulator module 510 includes a trace preprocessor module 516 configured to receive the enhanced address trace 512 as input and separates the enhanced address trace 512 into two portions. A first portion includes an address trace 520, without any embedded data, and the second portion includes trace metadata 522, which represents the embedded data, including control dependencies or other context, separated from the enhanced address trace 512.

A simulation engine module 518 of the memory controller simulator module 510 produces the simulation results 514 output from the memory controller simulator module 510. The simulation results 514 associate data, including control dependencies or other context, with the addresses shown in the address trace 520. Because the simulation engine module 518 incorporates the trace metadata 522 into an analysis of the address trace 520, the simulation results 514 are more accurate, or at least more detailed than simulation results produced without embedding data in an address stream during a test. The memory controller simulator module 510 is configured to use the enhanced address trace 512, which includes embedded data, to produce a more-accurate simulation of a memory design than if the address trace 520 is used without access to the trace metadata 522 to generate simulation results.

### Testing Operations

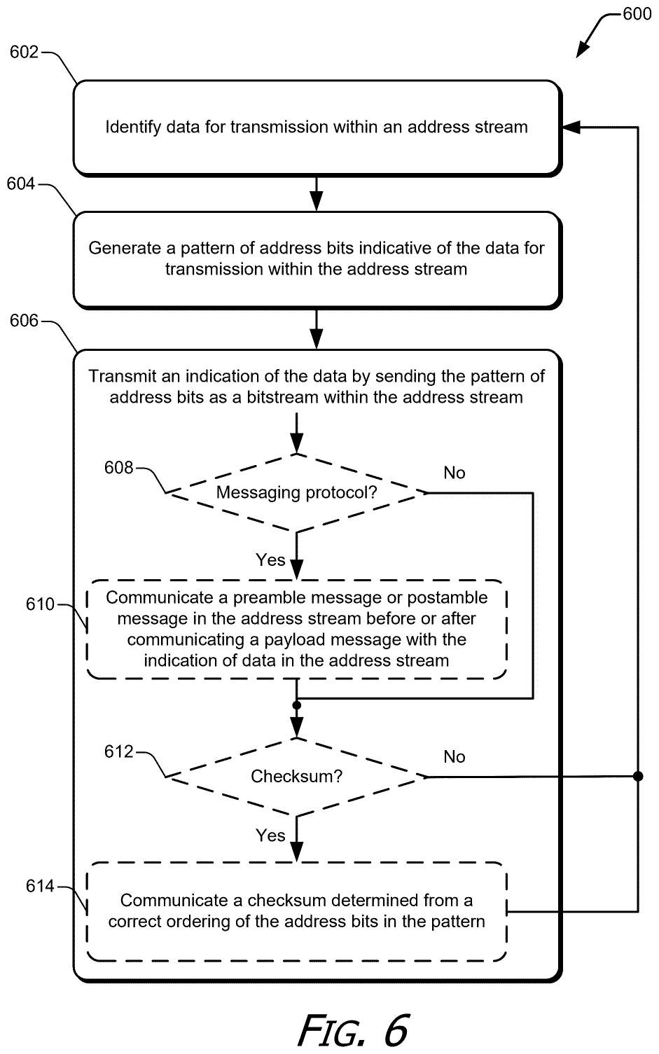

FIG. 6 illustrates an example process 600 with operations 602 through 614 performed by a computing system configured to embed data in an address stream, the address stream being separate from a data stream. As described throughout, the address stream and data stream are propagated over a single interconnect, such as a memory bus. For example, the computer 100 performs the operations 602 through 614 by executing instructions at a host device 102, such as instructions associated with the program 116 and/or a library, such as the library 314 or 316 from FIG. 3. Performance of the operations (or acts) 602 through 614 is not necessarily limited to the order or combinations in which the operations are shown in FIG. 6 or described herein. Further, any of one or more of the operations may be repeated, combined, or reorganized to provide other operations for embedding data in a data stream. In executing the operations 602 through 614, the computer 100 is therefore configured to communicate data 122 in an address stream 112 over a memory bus 110 extending between the host device 102 and a memory 108.

At 602, the computer 100 identifies data for transmission within an address stream. For example, the host device 102 receives data from the program 116, which while executing at the processors 104, calls on the library 314 or 316 to invoke one or more functions. When invoked by the program 116, the library 314 or 316 directs the host device 102 to send data 122 within the address stream 112.

At 604, the computer 100 generates a pattern of address bits indicative of the data for transmission within the address stream. For example, while executing at the host device 102, the library 314 packages the data 122 received as input from the program 116, into a format suitable for communication through the address stream 112. The pattern of address bits indicative of data may be formulated in accordance with the repetition-based pattern of FIG. 2-1, the message-based pattern of FIG. 2-2, and so forth. The pattern of address bits may include a checksum, a sequence indicator per address, and the like.

At 606, the computer 100 transmits an indication of the data by sending the pattern of address bits as a bitstream within the address stream. Here, the bitstream includes multiple bits and occupies a portion of the address stream 112 and includes data or an indication of data instead of address information. For instance, the packaged data 122 from step 604 is output by the memory controller 106 onto the address stream 112. An indication of the packaged data 122 appears on the address lines of the memory bus as an. The encoded series of one or more addresses, rather than conveying an address for a read or write request, informs the memory 108 or other recipient of the address stream 112 (e.g., the logic analyzer module 502) that data is being transferred from the host device 102 over the address stream 112.

At 606, the computer 100 can transmit the indication of the data in various ways, as described throughout this document. Each of the operations 608, 610, 612, and 614 are optional and not required but can promote reliability or security in sending data through an address stream.

At 608, the computer 100 determines whether to use a messaging protocol. If so, when a recipient of the address stream 112 is configured to detect a preamble message, a payload message, and/or postamble message, the computer 100 includes at 610 the data 122, or an indication of how the data 122 is referenced in relation the memory 108, as part of the payload message. For example, the address bits communicated through the address stream may represent the data 122, or they may indicate an offset to a page of the memory 108 which is reserved by the program 116 to communicate the data 122 over an address stream 112. In other implementations, the pattern of address bits may be repeatedly transmitted (e.g., in n cycles) within a window 208 of time to indicate that data is present in the address stream 112.

Alternatively, when the recipient of the address stream 112 is not configured for communicating using the messaging protocol described herein, the computer 100 may bypass operation 610 and proceed to operation 612. In such cases, the computer may include the data 122 as an encoded series of address bits, which are subsequently identifiable from a memory trace or by the recipient. Or, still bypassing step 610, the computer 100 can communicate an indication of the data 122 without relying on the described messaging protocol by transmitting address bits that indicate a page that is reserved for communicating the data 122 to the memory 108.

At 612, the computer 100 determines whether the communication of the data 122 is to include a checksum, such as a CRC checksum, in the event the memory bus 110 rearranges some of the address stream 112 so that parts of the data 122 appear out-of-order when communicated through the address stream 112. The checksum can be used by a recipient to determine a correct ordering of the address bits to determine the data 122 or mailbox location of the data 122. If the checksum is not being used, the computer 100 returns to operation 602 to repeat the process 600, if additional data is identified.

At 614, the computer communicates a checksum determined from a correct ordering of the address bits in the pattern. For example, a library routine of the host device 102, e.g., the library 314 or 316, determines a pattern of address bits or inter-address deltas for conveying the data 122, and determines a checksum based on the pattern so that if parts of the data 122 are interspersed with addresses, or otherwise rearranged in a different order than the host device 102 intended, the recipient can order the address bits to determine the data 122. Said differently, the host 102 may output the indication of data 122 as an unordered group of addresses that appear in the address stream 112. The processors 104 are configured to include, within the unordered group of addresses, one or more offsets that represent a checksum corresponding to remaining offsets from the unordered group of addresses arranged in a correct order.

A recipient of the address stream 112, may verify the data 122, such as a condition to outputting the data 122 on the interconnect 508 as part of a memory trace of the memory bus 110. Here, the embedded-data receiver module 312-1 or other recipient determines a plurality of offsets contained in the address stream 112. Based on the offsets, a particular offset in an ordered-combination of the plurality of offsets includes a checksum that is computed based on the remaining offsets in the ordered-combination.

For example, the payload message 404-1 includes the offsets [A, B, C] in any order. Two of the offsets, when concatenated together, satisfy the CRC checksum indicated by the third offset. To analyze these three offsets, the embedded-data receiver module 312-1 or other recipient can try each combination of the offsets [A, B, C] until a combination of two offsets produce a CRC checksum indicated by the third offset. In this example, the offsets “C” and “A,” when concatenated together as “C+A,” produce the CRC checksum value “B.” The embedded-data receiver module 312-1 can isolate the offsets that represent the data 122 from the offset(s) that represent the CRC checksum. That is, responsive to determining a particular offset comprises a CRC checksum for the remaining offsets, the embedded-data receiver module 312-1 may identify the remaining offsets in the ordered-combination as being the data 122 communicated by the program 116 in the address stream 112. In other implementations, such as those that omit a checksum or that use a checksum that does not reflect data order, a sequence indicator may be included in the address stream as part of each offset having payload data in a group of related offsets.

The data 122 may indicate a mailbox 200 location corresponding to a page of memory allocated to a program that initiated the communication of the data. For example, the offsets A and B concatenate together forming mailbox location AB, which passes a CRC checksum equal to C. The program 116 can write additional data to the mailbox location AB in another payload message 404, without invoking the library 314 or 316 and/or without sending another preamble message 402. The embedded-data receiver module 312-1 or other recipient is programmed to recognize addresses in the address stream 112, including the page (e.g., page “B”) where the mailbox is established.

Acts 606 through 614 may be repeated to, for example, enable the program 116 to output another payload message 404, or additional data, such as a new execution context indicator (e.g., a thread ID, a process ID, or a program counter (PC)).

Although some of the description herein refers to the embedded-data receiver module 312 processing an address stream 112 or taking actions based on detected data, these descriptions may also or instead apply to acts performed by a logic analyzer or other recipient device that monitors the address stream 112 (e.g., separately during or after a test has been concluded).

### Simulation Operations

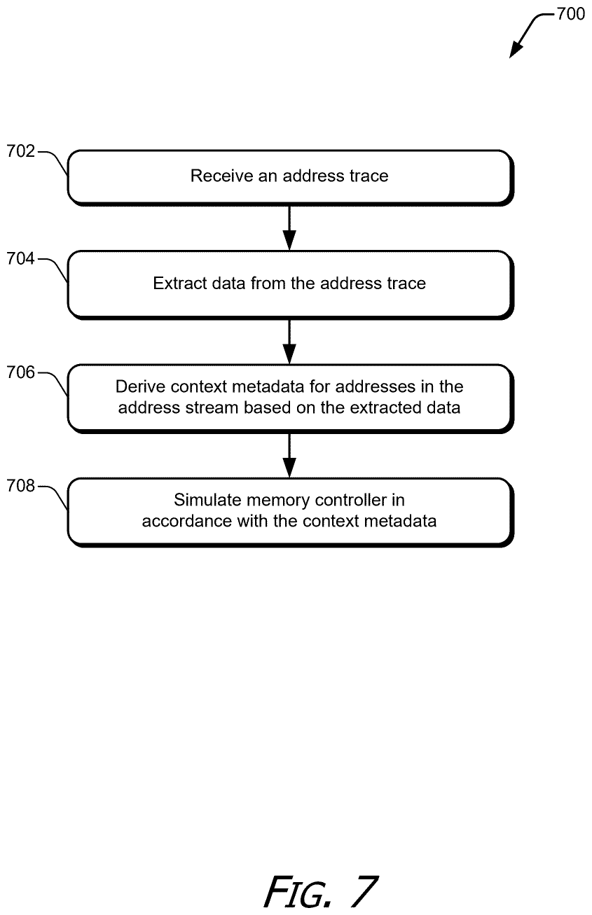

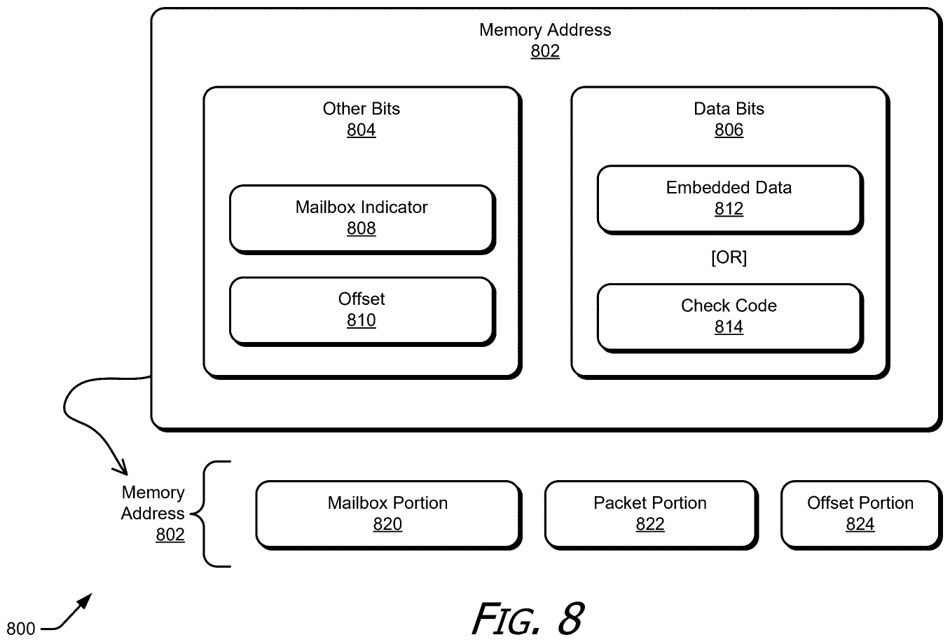

FIG. 7 illustrates an example process 700 with operations 702 through 708 performed by a computing system configured to extract or interpret data embedded within an address stream that is propagated over a memory bus or other interconnect beings probed or monitored, e.g., during a memory test. For example, the memory controller simulator module 510 performs the operations 702 through 708 when instructions associated with the memory controller simulator module 510 are loaded by a processor. Performance of the operations (or acts) 702 through 708 is not necessarily limited to the order or combinations in which the operations are shown in FIG. 7 or described herein. Further, any of one or more of the operations may be repeated, combined, or reorganized to provide other operations for interpreting data embedded in an address stream.

At 702, the memory controller simulator module 510 receives an address trace. For example, the memory controller simulator module 510 obtains as input, the enhanced address trace 512, which is stored by the logic analyzer module 502, for example, within the computer-readable storage medium 302-1.

At 704, the memory controller simulator module 510 extracts data from the address trace. For example, the trace preprocessor module 516 receives the enhanced address trace 512 as input and divides the enhanced address trace 512 into the address trace 520, without any embedded data, and the trace metadata 522. The data can include a preamble message, a postamble message, a checksum, a payload message, and the like, as described throughout the disclosure.

At 706, the memory controller simulator module 510 derives context metadata for addresses in the address stream based on the extracted data. For example, the simulation engine module 518 derives control dependencies, thread identifiers, program counters, or other contextual information from the trace metadata 522 to use as inputs or variables for enhancing a simulation.

At 708, the memory controller simulator module 510 simulates a memory controller in accordance with the context metadata derived at 706. For example, the simulation engine module 518 uses the control dependencies, thread identifiers, program counters, or other contextual information derived from the trace metadata 522 to annotate or highlight portions of the address trace 520. This way the simulation results 514 that are output by the simulation engine module 518 are enhanced to include meaningful information about the context of addresses observed during the test.

While the techniques for embedding and extracting data from within an address stream are primarily described as promoting memory tests and memory simulations, there are many other use cases for embedding data within address streams. For example, the data can be used by the memory 108 or the host device 102 to align system or software events with their memory activity, for example, when analyzing memory behavior to debug software issues with execution of the program 116. The data may convey parameters or data, which when embedded in an address stream, direct internal functions or parameters of the memory 108, for example, by specifying values or states of memory-side hardware-registers that configure accelerators or other components of the memory 108.

### Example Operating Environments

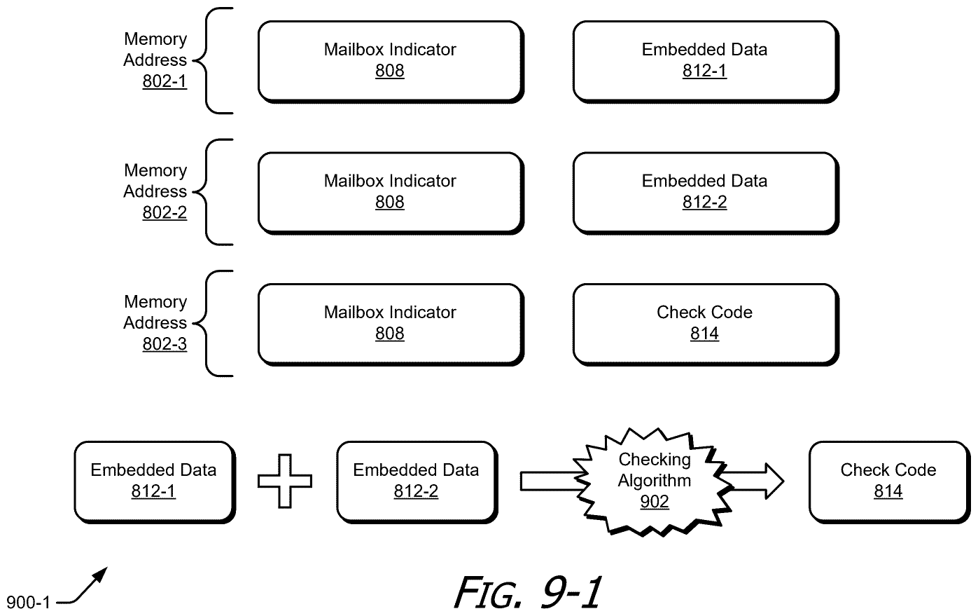

FIG. 8 illustrates, at 800 generally, example aspects of a memory address 802 that can be used to communicate data, including to establish or use a mailbox. A memory address 802 typically includes multiple bits that identify an address of a memory location that is targeted by a memory operation, such as a read or write operation. As described herein, however, a memory address 802 can include data as part of a logical or virtual channel that communicates data using an address channel, including an address bus in some cases.

As illustrated, a memory address 802 can include at least other bits 804 and data bits 806. The data bits 806 can include embedded data 812 or a check code 814, including embedded data 812 and check code 814 in some implementations in accordance with a permitted, but optional, interpretation of the word “or” as an “inclusive-or” term. As described herein, the check code 814 can be realized with a cyclic redundancy check (CRC) code like a checksum, with an error correction code (ECC), and so forth. The other bits 804 can include a mailbox indicator 808 or an offset 810. As described herein, the offset 810 may relate to the lower order bits of a memory address 802 that map into a cache line; thus, the offset 810 may not be transmitted to a memory device in some scenarios.

In example implementations, the mailbox indicator 808 is a quantity of other bits 804 that identify an allocated address region of a memory. The allocated address region may be of any size, such as a page, multiple pages, and so forth. The mailbox indicator 808 may correspond, for example, to a base address of the mailbox. As shown at the lower portion of FIG. 8, the bits that form a memory address 802 can include a mailbox portion 820, a packet portion 822, and an offset portion 824. The packet portion 822 can correspond to the data bits 806, so the packet portion 822 can include at least part of the embedded data 812, at least part of the check code 814, some combination thereof, and so forth.

In each computing architecture or operational mode, the quantity of bits of the memory address 802 may be fixed. Thus, there may be a tradeoff between the two or more portions of the memory address 802. In other words, if the mailbox portion 820 is shortened to have fewer bits, then the packet portion 822 can be lengthened to have more bits. By way of example only, with a given memory address having 52 bits and a 6-bit offset portion 824 (for a 64-byte cache line), the remaining 46 bits can be split between the mailbox portion 820 and the packet portion 822. A 40-bit mailbox portion 820 leaves six bits for the packet portion 822. Increasing the size of mailbox can decrease the length of the mailbox portion 820 to increase the length of the packet portion 822. For instance, a 30-bit mailbox portion 820 leaves 16 bits, or two full bytes, for the packet portion 822. However, a memory address 802 may have different portions, and such portions may have different bit lengths.

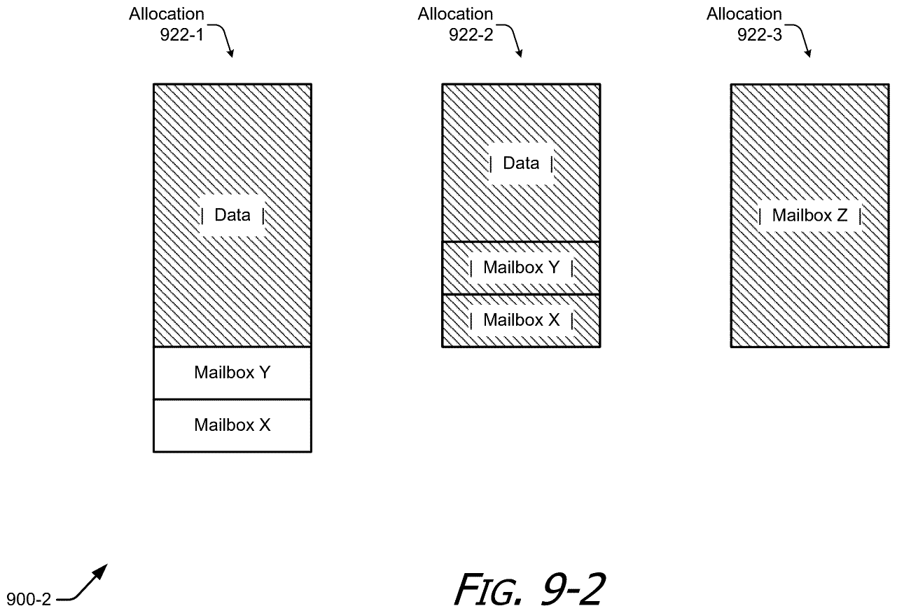

FIG. 9-1 illustrates, at 900-1 generally, an example set of memory addresses 802-1 to 802-3 that can jointly communicate data using a mailbox or a check code, including both a mailbox and a check code in some cases. As shown, each memory address 802 includes at least one mailbox indicator 808 and at least one instance of data bits 806 (e.g., of FIG. 8), such as embedded data 812 or a check code 814. In example implementations, a set of memory addresses includes a first memory address 802-1, a second memory address 802-2, and a third memory address 802-3. These three memory addresses 802-1, 802-2, and 802-3 can be linked together by a relationship between the embedded data 812 and the check code 814.

The first memory address 802-1 includes a mailbox indicator 808 (e.g., as at least part of first other bits) and a first part of the embedded data 812-1. The second memory address 802-2 includes the mailbox indicator 808 (e.g., as at least part of second other bits) and a second part of the embedded data 812-2. The third memory address 802-3, or at least one memory address generally, includes the mailbox indicator 808 (e.g., as at least part of third other bits) and a corresponding check code 814. Thus, the first other bits can be equal to the second other bits, and the second other bits can be equal to the third other bits as being part of, delivered to, the same mailbox. In some cases, the check code 814 is “confined” to a single memory address 802; however, a check code 814 may be distributed across two or more memory addresses. The check code 814 corresponds to the first embedded data 812-1 and the second embedded data 812-2 in relation to a checking algorithm 902, which is described next.

A relationship can be established between at least one instance of the embedded data 812 (e.g., two or more instances of the embedded data 812) and at least one check code 814. For example, applying the at least one embedded data 812 to a function, such as a checking algorithm 902, produces a check code 814. In the illustrated example, the first part of the embedded data 812-1 and the second part of the embedded data 812-2 are applied to the checking algorithm 902 to produce the corresponding check code 814. Examples of the checking algorithm 902 include a CRC algorithm and an ECC algorithm, but others may be used instead. As described herein, the relationship between the at least one instance of embedded data 812 and the corresponding check code 814 can be used to identify embedded data in the address stream, including how multiple parts of the embedded data 812 may be related to each other. In some aspects, a reasonable tradeoff between performance and reliability can be achieved using two packets with embedded data 812 and one packet with the corresponding check code 814. Other organizations, however, may be employed, such as four packets with embedded data 812 and two packets with a check code 814 for one relationship.

FIG. 9-2 illustrates, at 900-2 generally, multiple different example memory allocations 922-1 to 922-3 for at least one mailbox. In a first example memory allocation 922-1, a program allocates a first mailbox “X” and a second mailbox “Y” separately from an address region for the data of the program. However, because reads are non-destructive, an application can overlay a mailbox on top of any data owned by the application. This enables the mailbox-based technique to be implemented with zero space overhead. As shown in a second example memory allocation 922-2, a program allocates a first mailbox “X” and a second mailbox “Y” over an address region for the data of the program. With a third example memory allocation 922-3, a program allocates a mailbox “Z” over an entire address region for the data of the program.

Use of a dedicated mailbox window can remove most read traffic (reads that have to be decoded), but the decoding still works in the presence of other traffic. Larger mailbox windows can also reduce the impact of prefetching because the larger memory range spreads out the addresses in space. This reduces the likelihood of streams being detected and the prefetcher attempting to issue requests. To further reduce prefetches, an invertible randomizer (e.g., a Feistel network) can be used to reduce the correlation between packets and to increase the distance between addresses, which reduces the chance of triggering prefetches.

For reliable operation, mailboxes are implemented to have a contiguous physical address space. This can be guaranteed by using an operating system page size that is larger than the mailbox, or a special memory allocation scheme can be implemented that maintains contiguous virtual and physical address range mappings. Although certain example memory allocations are depicted in FIG. 9-2 and described herein, other memory allocations can be implemented instead. For example, mailbox memory allocations for a same program can have different sizes, or mailbox memory allocations for a same program may not be contiguous.

### Example Techniques and Hardware

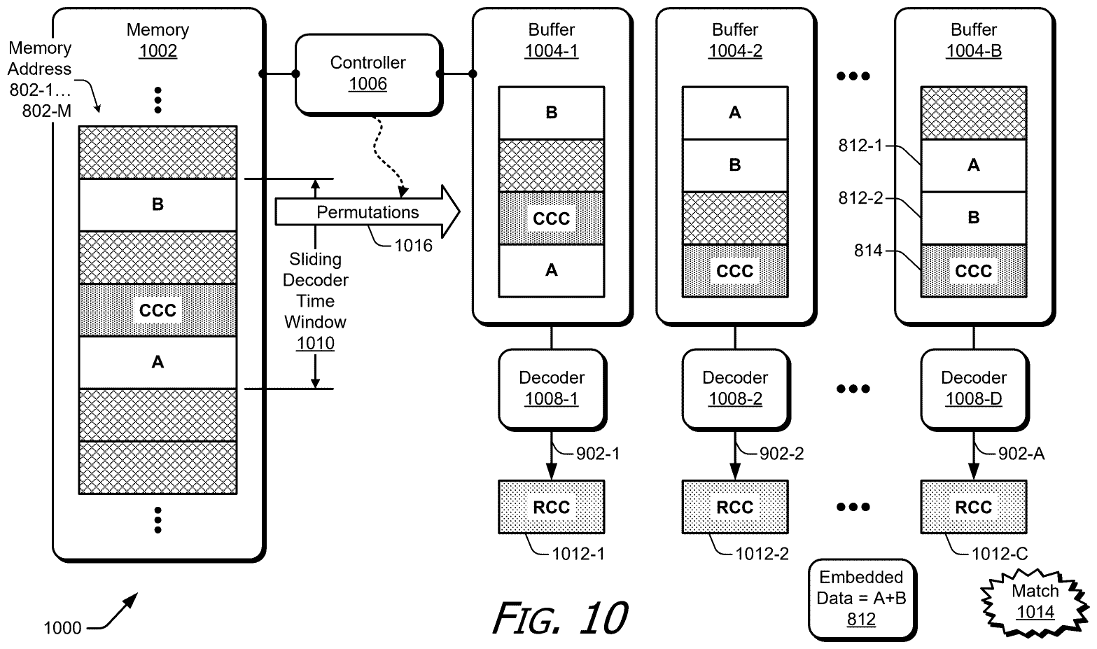

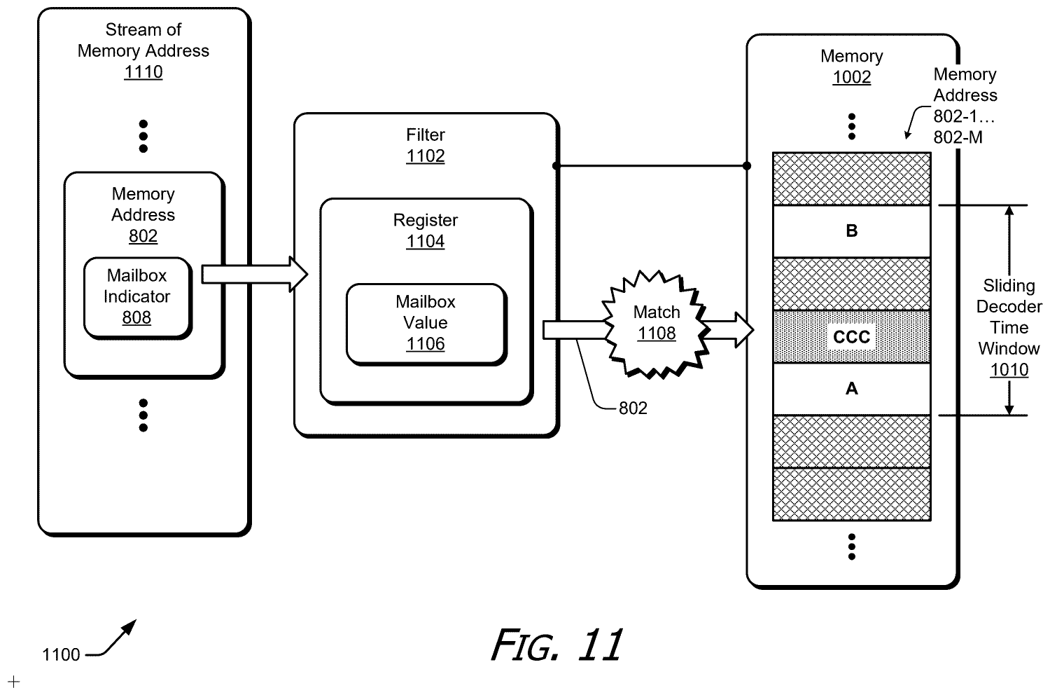

FIG. 10 illustrates an example architecture 1000 for obtaining data from a memory address stream using a check code, which processing can include using a mailbox as described herein. As shown, the architecture 1000 includes at least one memory 1002; multiple buffers 1004-1, 1004-2, . . . 1004-B (with B being an integer greater than one); at least one controller 1006; and multiple decoders 1008-1, 1008-2, . . . 1008-D (with D being an integer greater than one, which may be the same as or different from B). Each memory address 802 can include data “A” (with no fill pattern), data “B” (with no fill pattern), a corresponding check code “CCC” (with a dense dotted pattern), or any general bits (with a cross-hatched fill pattern).

In example implementations, the memory 1002 stores the multiple memory addresses 802-1 . . . 802-M (with M being an integer greater than one). The multiple memory addresses 802-1 . . . 802-M include embedded data 812 and a corresponding check code 814 (e.g., of FIG. 8). The multiple buffers 1004-1 . . . 1004-B are coupled to the memory 1002. Each respective buffer 1004 of the multiple buffers 1004-1 . . . 1004-B stores a respective portion of memory addresses of the multiple memory addresses 802-1 . . . 802-M. The respective portion of memory addresses can correspond to at least part of a sliding decoder time window 1010.

The controller 1006 is coupled to the memory 1002 and the multiple buffers 1004-1 . . . 1004-B. The controller copies the respective portion of memory addresses from the memory 1002 to each respective buffer 1004. Each respective decoder 1008 of the multiple decoders 1008-1 . . . 1008-D is coupled to a respective buffer 1004 of the multiple buffers 1004-1 . . . 1004-B. In example operations, each respective decoder 1008 is configured to compute a respective check code 1012 (with a sparse dotted fill patten) of multiple respective check codes 1012-1, 1012-2, . . . 1012-C (with C being an integer greater than one, which may be the same as or different from B or D). Each respective decoder 1008 can compute a respective check code 1012 (RCC 1012) based on the respective portion of memory addresses stored in each respective buffer 1004. Each respective decoder 1008 is also configured to search for the embedded data 812 using a comparison including the respective check code 1012 and at least one memory address 802 of the respective portion of memory addresses stored in each respective buffer 1004. For example, each decoder 1008 can compare embedded data 812 from two or more memory addresses 802 (e.g., a combination of “A” and “B,” such as a concatenation “A+B”of embedded data) to a computed respective check code 1012.

In some cases, a respective decoder 1008 (e.g., the decoder 1008-D in the depicted example) of the multiple decoders 1008-1 . . . 1008-D can identify the embedded data 812 based on the respective check code 1012 (e.g., the RCC 1012-C) matching 1014 the corresponding check code “CCC” 814 that is included as at least part of the at least one memory address 802 of the respective portion of memory addresses stored in the respective buffer 1004 (e.g., the buffer 1004-B in the depicted example). The respective decoder 1008 can also signal identification of the embedded data 812 responsive to the matching 1014. The signaling can be communicated to the controller 1006, another circuit that may use the embedded data 812, a program or module executing on a logic analyzer or other testing apparatus, and so forth.

In some aspects, to compute the check code 1012, the respective decoder 1004 applies a checking algorithm 902 of multiple checking algorithms 902-1, 902-2, . . . 902-A (with A being an integer greater than one, which may be the same as or different from A, B, or D) to the first part of the embedded data 812-1 (e.g., of FIG. 9-1) “A” and the second part of the embedded data 812-2 “B” to produce the respective check code 1012. By way of example only, the checking algorithm 902 can include a cyclic redundancy code (CRC) algorithm, and the corresponding check code 814 can include a checksum. The check code 814 can have a value that is dependent on the order in which the first and second parts of the embedded data 812 are applied to the checking algorithm 902.

The controller 1006 can load all or part of each memory address 802 into the multiple buffers 1004-1 . . . 1004-B. For example, the mailbox portion 820 or the offset portion 824 (e.g., of FIG. 8) (including both in some cases) can be excluded from the copying. Thus, the controller 1006 can copy, to each respective buffer 1004, the first part of the embedded data 812-1, the second part of the embedded data 812-2, and the corresponding check code 814. Further, the controller 1006 may exclude first other bits, second other bits, or third other bits from the copying to each respective buffer 1004, with the other bits 804 (e.g., of FIG. 8) corresponding to bits that are not data bits 806.

To identify a set of memory addresses within the memory 1002 that include embedded data 812, multiple sets of memory addresses may need to be checked to determine a quantity of memory addresses or an order of memory addresses that have one or more parts of embedded data 812 that align with a corresponding check code 814. In some cases, the controller 1006 can copy memory addresses from the memory 1002 to the buffers 1004-1 . . . 1004-B in a same order. In these cases, each respective decoder 1008 may extract the copied bits of the memory addresses in different order. For instance, one decoder 1008 may check the “top” three memory storage locations, and another decoder 1008 may check “bottom” three memory storage locations. Different decoders 1008 may also check the same “top” three memory storage locations in different manners, such as one decoder 1008 testing a first storage location as potentially having a corresponding check code “CCC,” and another decoder 1008 testing a second different storage location as potentially having a corresponding check code “CCC.”

Alternatively, the controller 1006 may copy the selected portions of the multiple memory addresses 802-1 . . . 802-M to the multiple buffers 1004-1 . . . 1004-B in different permutations. For example, the controller 1006 can copy the respective portion of memory addresses from the memory 1002 to each respective buffer 1004 by copying the respective portion of memory addresses, which may be within the sliding decoder time window 1010, from the memory 1002 to each respective buffer 1004 in different orders. For instance, the controller 1006 can load the memory addresses of the respective portion of memory addresses into each respective buffer 1004 in a different permutation order 1016. Three example permutation orders are explicitly depicted in FIG. 10.

With the memory addresses copied over in different orders, each respective decoder 1008 can check for a match 1014 using the same storage locations in each respective buffer 1004. For example, each buffer 1004 of the multiple buffers 1004-1 . . . 1004-B can include multiple storage locations, with each storage location represented by a rectangular block in FIG. 10. The controller 1006 loads respective instances of the memory addresses 802 of the respective portion of memory addresses into each respective buffer 1004 at different storage locations of the multiple storage locations. Thus, in some aspects, each respective decoder 1008 can compute the respective check code “RCC” 1012 by accessing a same set of storage locations of the multiple storage locations of each respective buffer 1004. Moreover, the controller 1006 may copy over to a respective buffer 1004 those memory addresses 802 designated to be checked by a respective decoder 1008 and exclude one or more other memory addresses from copying. With reference to FIG. 10, for instance, the top storage location can be left “empty”or omitted from being physically realized in a given architecture.

In some aspects, the quantity of storage locations in each buffer may be different from the quantity of memory addresses 802 applied for each checking algorithm 902. For example, each buffer 1004 of the multiple buffers 1004-1 . . . 1004-B can include multiple storage locations, with the multiple storage locations have a first quantity of storage locations. Each respective decoder 1008 can compute the respective check code “RCC” 1012 using a subset of memory addresses of the respective portion of memory addresses stored in the respective buffer 1004. The subset of memory addresses may have a second quantity of memory addresses. The first quantity, which represents a number of storage locations, may be greater than the second quantity, which represents a number of memory addresses. Further, the multiple buffers 1004-1 . . . 1004-B may have a third quantity of buffers. To check for embedded data at least substantially simultaneously (e.g., with there being at least some temporal overlap across each of the checking operations) across multiple permutations, the third quantity of buffers is set equal to or greater than a number of permutation orders that are possible for the memory addresses 802 stored in the multiple storage locations having the first quantity of storage locations in each buffer 1004. For instance, with four memory addresses 802 taking three at a time wherein an order of the three matters, there can be at least 24 buffers 1004 (e.g., B>=24). This corresponds to a permutation calculation of P(4,3) or 4!/(4-3)!.

In some situations, the memory 1002 may include multiple memory addresses 802-1 . . . 802-M that have different mailbox portions 820 (e.g., of FIG. 8), or different potential mailbox portions 820. In at least some of such situations, if a system is utilizing a technique that involves a mailbox, each decoder 1008 should operate on a group of memory addresses 802 having a same mailbox portion 820 to attempt to identify embedded data 812. In example aspects, at least some memory addresses 802 of the multiple memory addresses 802-1 . . . 802-M include a mailbox portion 820 and a packet portion 822 (each of FIG. 8). The mailbox portion 820 includes a mailbox indicator 808 that is indicative of an association between two or more memory addresses 802, such as that the associated memory addresses 802 are part of a same mailbox that realizes a data channel embedded in an address stream. The packet portion 822 includes at least one instance of embedded data 812 or at least one instance of a check code 814.

The controller 1006 can use the mailbox indicator 808 to assign a memory address 802 to a buffer 1004 that is associated with other memory addresses with the same mailbox indicator 808. For example, the controller 1006 can copy a respective portion of memory addresses (e.g., at least part of those memory addresses 802 in the sliding decoder time window 1010) from the memory 1002 to each respective buffer 1004 of the multiple buffers 1004-1 . . . 1004-B based on the mailbox indicator 808 in each memory address 802 of the multiple memory addresses 802-1 . . . 802-M.

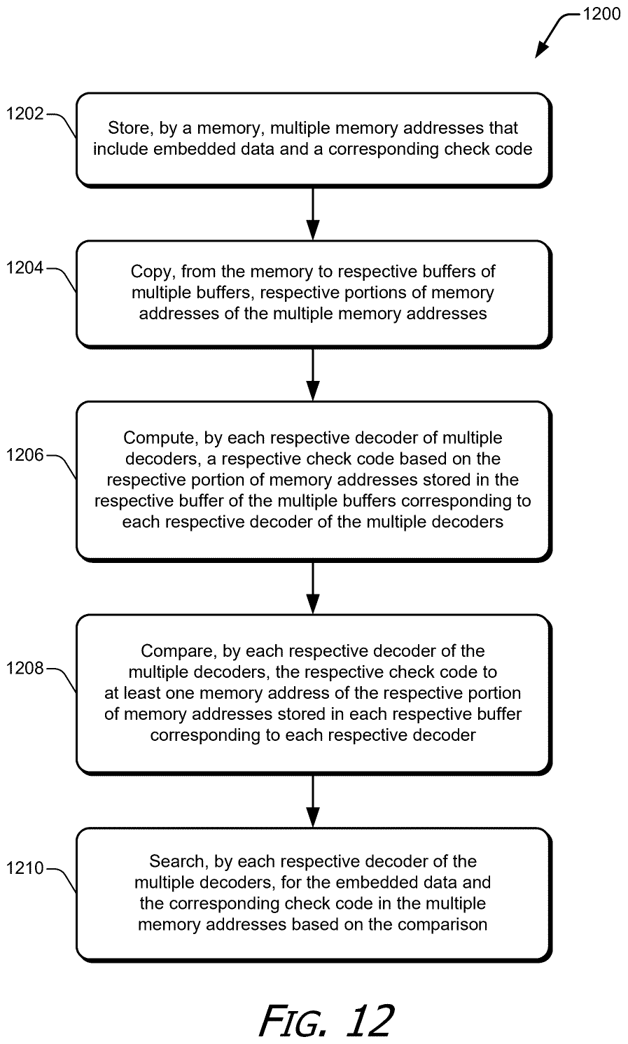

The multiple buffers 1004-1 . . . 1004-B and corresponding multiple decoders 1008-1 . . . 1008-D of FIG. 10 can be used to quickly and efficiently identify embedded data 812, if present, amongst a time window of multiple memory addresses 802-1 . . . 802-M. Further, as described herein by way of example, a mailbox memory allocation can be determined (e.g., detected) by copying the memory addresses 802 having common other bits 804 that might be a mailbox indicator 808 to a same buffer 1004. By discovering at least one memory address 802 with a check code 814 that matches 1014 to another memory address 802 with a mailbox allocation signature, a mailbox can be determined, e.g., based on a common mailbox portion 820 of the two or more memory addresses 802. Once a mailbox memory allocation has been determined, the memory 1002 can be used more efficiently as described next with reference to FIG. 11.

FIG. 11 illustrates an example architecture 1100 for filtering memory addresses 802 based on a mailbox value that is indicative of a mailbox memory allocation. A stream of memory addresses 1110 includes a plurality of memory addresses provided over an address channel, such as an address bus or command channel. The stream of memory addresses 1110 includes a memory address 802 having a mailbox indicator 808. If a mailbox memory allocation is known, then extracting embedded data 812 from multiple memory addresses 802-1 . . . 802-M can be facilitated by excluding from the memory 1002 those memory addresses that do not have the same bits as the determined mailbox. To do so, a filter 1102 controls which memory addresses are loaded into the memory 1002 based on a mailbox value 1106 stored in a register 1104 of the filter 1104. Here, the mailbox value 1106 can be set equal to a determined mailbox having a mailbox indicator 808.

In example implementations, the filter 1102 is coupled to the memory 1002. The filter 1102 includes at least one register 1104 that is configured to store at least one mailbox value 1106. In example operations, the filter receives a stream of memory addresses 1110 having a plurality of memory addresses that include the multiple memory addresses. The stream of memory addresses 1110 includes mailbox portions 820 (e.g., of FIG. 8). The filter 1102 also performs a filter comparison including the mailbox portions 820 of the stream of memory addresses 1110 and the at least one mailbox value 1106. The filter 1102 further loads the memory 1002 with the multiple memory addresses 802-1 . . . 802-M based on the filter comparison. For instance, the multiple memory addresses 802-1 . . . 802-M may have mailbox indicators 808 that match 1108 the mailbox value 1106, so these memory addresses 802 are loaded into the memory 1002. Other memory addresses of the plurality of memory addresses have other bits 804 that do not match the mailbox value 1106. These other memory addresses are therefore not loaded into the memory 1002. Such other memory addresses can still, however, be processed in other manners to search for embedded data.

### Example Methods

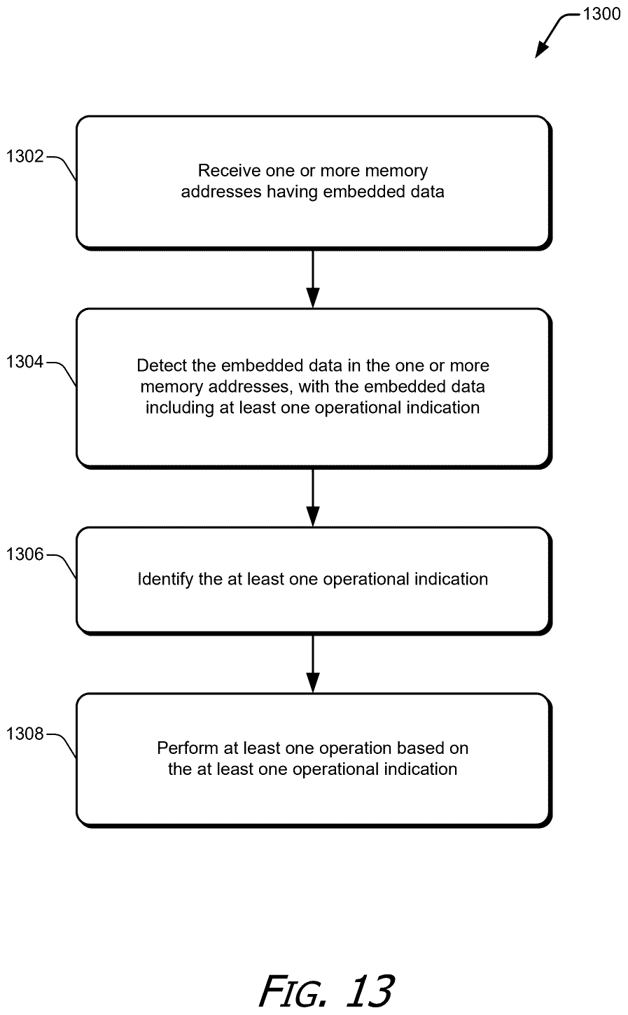

This section describes example methods for implementing aspects of utilizing data embedded in address streams with reference to the diagrams of FIGS. 12 and 13. This description may also refer to components, entities, and other aspects depicted in FIGS. 1 to 12 by way of example only. The described methods are not necessarily limited to performance by one entity operating on one device or module.

FIG. 12 illustrates an example method 1200 for utilizing data embedded in address streams. As shown, the method 1200 can include five blocks 1202 and 1210. At 1202, a memory stores multiple memory addresses that include embedded data and a corresponding check code. For example, a memory 1002 can store multiple memory addresses 802-1 . . . 802-M that include embedded data 812 and a corresponding check code 814.

At 1204, respective portions of memory addresses of the multiple memory addresses are copied from the memory to respective buffers of multiple buffers. For example, respective portions of memory addresses of the multiple memory addresses 802-1 . . . 802-M can be copied from the memory 1002 to respective buffers of multiple buffers 1004-1 . . . 1004-B. Each respective portion may be the same as one or more other respective portions, be different from one or more other respective portions, have the same content but different ordering than one or more other respective portions, some combination thereof, and so forth.

At 1206, each respective decoder of multiple decoders computes a respective check code based on the respective portion of memory addresses stored in the respective buffer of the multiple buffers corresponding to each respective decoder of the multiple decoders. For example, each respective decoder 1008 of multiple decoders 1008-1 . . . 1008-D can compute a respective check code 1012 (“RCC”) based on the respective portion of memory addresses stored in the respective buffer 1004 of the multiple buffers 1004-1 . . . 1004-B corresponding to each respective decoder 1008 of the multiple decoders 1008-1 . . . 1008-D.

At 1208, each respective decoder of the multiple decoders compares the respective check code to at least one memory address of the respective portion of memory addresses stored in each respective buffer corresponding to each respective decoder. For example, each respective decoder 1008 of the multiple decoders 1008-1 . . . 1008-D can compare the respective check code 1012 (“RCC”) to at least one memory address 802 of the respective portion of memory addresses stored in each respective buffer 1004 corresponding to each respective decoder 1008. In some cases, the at least one memory address 802 may contain a corresponding check code 814 (“CCC”) that matches 1014 with the computed respective check code 1012 (“RCC”).

At 1210, each respective decoder of the multiple decoders searches for the embedded data and the corresponding check code in the multiple memory addresses based on the comparing. For example, each respective decoder 1008 of the multiple decoders 1008-1 . . . 1008-D can search for the embedded data 812 and the corresponding check code 814 (“CCC”) in the multiple memory addresses 802-1 . . . 802-M based on the comparing. By comparing the computed respective check code 1012 (“RCC”) to the at least one memory address 802 of the respective portion of memory addresses stored in each respective buffer 1004 corresponding to each respective decoder 1008, each respective decoder 1008 may search for a match 1014 to the corresponding check code 814 (“CCC”), which is indicative of identifying the embedded data 812.

FIG. 13 illustrates another example method for utilizing data embedded in address streams. As shown, the method 1300 can include five blocks 1302 and 1308. The method can be performed by, for instance, a memory device. The memory device can be realized with, for example, a DIMM; a SIMM; a memory module; a memory accelerator; a DRAM IC chip; a Compute Express Link® (CXL®) module—or component thereof such as a CXL interface, a memory controller that is internal thereto, or a DRAM chip; and so forth.

At 1302, one or more memory addresses having embedded data are received. For example, a memory device 108 can receive one or more memory addresses 802 having embedded data 812. The memory device 108 may receive the one or more memory addresses 802 via a general memory bus 110 or other interconnect 110 or via an address-specific memory bus, such as a command and address bus. At 1304, the embedded data is detected in the one or more memory addresses, with the embedded data including at least one operational indication. For example, the memory device 108 can detect the embedded data 812 in the one or more memory addresses 802, with the embedded data 812 including at least one operational indication. In some cases, the memory device 108 may employ the architecture 1000 or 1100 to detect the embedded data 812. The operational indication may correspond, for instance in a memory-related scenario, to an allocation of a memory object, to a start of a program loop (e.g., a “for”loop), some combination thereof, and so forth.

At 1306, the at least one operational indication is identified. For example, logic circuitry at the memory device 108 can identify the detected embedded data 812 as providing the at least one operational indication based on a comparison of a value of the embedded data 812 to one or more operational codes corresponding to one or more operations. At 1308, at least one operation is performed based on the at least one operational indication. For example, the memory device 108 can perform at least one operation based on the identified at least one operational indication. The at least one operation may include or correspond to at least one memory-related operation, at least one non-memory-related operation, some combination thereof, and so forth.

To perform at least one memory-related operation based on at least one operational indication, the memory device may, for instance, communicate to a host device that an allocated address range is adversely impacting memory performance, such as if there are excessive bank conflicts. Additionally or alternatively, the memory device may perform at least one memory-related operation by tracking behavior of an allocated address range and implementing a memory enhancement technique based on the tracking. To do so, the memory device may prefetch data into a memory-side cache based on the tracking of the behavior of the allocated address range, such as upon the next occurrence of the operational indication or a return to the same allocated address range.

To perform at least one non-memory-related operation based on at least one operational indication, the memory device may, for instance, utilize a near-memory computing (NMC) unit having one or more processors. Additionally or alternatively, the memory device may utilize processor-in-memory (PIM) circuitry. In some environments, NMC may entail PIM circuitry. Thus, to perform at least one non-memory-related operation, a memory device may use a near-memory computing unit to perform a non-memory-related compute operation, such as one involving vector or array-based computation for artificial intelligence (AI), graphics manipulation, and so forth. As another example, a memory device may execute, using one or more registers of a near-memory computing unit, at least one instruction. Execution of the at least one instruction may cause the memory device to transmit, using the one or more registers of the near-memory computing unit, one or more packets onto a network toward another device.

For the flow chart and flow diagram figures described above, the order in which operations are shown and/or described is not intended to be construed as a limitation. Any number or combination of the described process operations can be combined or rearranged in any order to implement a given method or an alternative method. Operations may also be omitted from or added to the described methods. Further, described operations can be implemented in fully or partially overlapping manners. Additionally, the processes and the operations thereof across the different methods may be implemented separately or in conjunction with one another.

Aspects of these methods may be implemented in, for example, hardware (e.g., fixed-circuit circuitry or a processor in conjunction with a memory), firmware, software, or some combination thereof. The method may be realized using one or more of the apparatuses, components, or other aspects shown in FIGS. 1 to 5-2 and 8 to 11, the components of which may be further divided, combined, rearranged, and so on. The devices and components of these figures generally represent hardware, such as electronic devices, packaged modules, IC chips, or circuits; firmware or the actions thereof; software; or a combination thereof. Thus, these figures illustrate some of the many possible systems or apparatuses capable of implementing the described methods.

Computer-readable media includes both non-transitory computer storage media and communication media including any medium that facilitates transfer of a computer program (e.g., an application) or data from one entity to another. Non-transitory computer storage media can be any available medium accessible by a computer, such as RAM, ROM, Flash, EEPROM, optical media, and magnetic media.

The entities of FIGS. 1 to 5 and 8 to 11 may be further divided, combined, or used with their respective illustrated components as described herein. The example operating environments 100 of FIG. 1, 500-1 of FIG. 5-1, and 500-2 of FIG. 5-2, as well as the detailed illustrations of FIGS. 2-1, 2-2, 3, 4, and 8 to 11 illustrate but some of many possible environments, systems, and devices capable of employing the described techniques. Furthermore, some of the processes and methods described in this document are depicted in FIGS. 6, 7, 12, and 13 as groups of blocks that specify operations performed, but the operations specified by the groups of blocks are not necessarily performed in the order or combination shown. Any of one or more of the operations may be repeated, combined, reorganized, or linked to provide a wide array of additional and/or alternate methods, including with other processes described herein. Also, the techniques are not limited to performance by one entity or multiple entities operating on one device, such as a single computer or a single processor. Instead the techniques may be performed by physically separate hardware that may be co-located at one facility or geographically dispersed.

In the following, various examples for implementing aspects of utilizing data embedded in address streams are described:

Example aspect 1: An apparatus comprising:
a memory configured to store multiple memory addresses, the multiple memory addresses comprising embedded data and a corresponding check code;
multiple buffers coupled to the memory, each respective buffer of the multiple buffers configured to store a respective portion of memory addresses of the multiple memory addresses;
a controller coupled to the memory and the multiple buffers, the controller configured to copy the respective portion of memory addresses from the memory to each respective buffer; and
multiple decoders, each respective decoder of the multiple decoders coupled to a respective buffer of the multiple buffers, each respective decoder configured to:
   compute a respective check code based on the respective portion of memory addresses stored in each respective buffer; and
   search for the embedded data using a comparison including the respective check code and at least one memory address of the respective portion of memory addresses stored in each respective buffer.

Example aspect 2: The apparatus of example aspect 1, or any other example(s) described herein, wherein a respective decoder of the multiple decoders is configured to:
identify the embedded data based on the respective check code matching the corresponding check code that is included as at least part of the at least one memory address of the respective portion of memory addresses stored in the respective buffer of the respective decoder; and
signal identification of the embedded data responsive to the matching.

Example aspect 3: The apparatus of example aspect 2, or any other example(s) described herein, wherein:
the respective portion of memory addresses stored in the respective buffer comprises a first memory address, a second memory address, and the at least one memory address;
the first memory address comprises a first part of the embedded data;
the second memory address comprises a second part of the embedded data; and
the at least one memory address comprises the corresponding check code.

Example aspect 4: The apparatus of example aspect 3, or any other example(s) described herein, wherein:
to compute the check code, the respective decoder is configured to apply a checking algorithm to the first part of the embedded data and the second part of the embedded data to produce the respective check code.

Example aspect 5: The apparatus of example aspect 4, or any other example(s) described herein, wherein:
the checking algorithm comprises a cyclic redundancy code (CRC) algorithm; and
the corresponding check code comprises a checksum.

Example aspect 6: The apparatus of example aspect 4, or any other example(s) described herein, wherein:
the first memory address comprises the first part of the embedded data and first other bits;
the second memory address comprises the second part of the embedded data and second other bits; and
the at least one memory address comprises the corresponding check code and third other bits.

Example aspect 7: The apparatus of example aspect 6, or any other example(s) described herein, wherein:
the first other bits are equal to the second other bits; and
the second other bits are equal to the third other bits.

Example aspect 8: The apparatus of example aspect 6, or any other example(s) described herein, wherein the controller is configured to:
copy, to each respective buffer, the first part of the embedded data, the second part of the embedded data, and the corresponding check code; and
exclude the first other bits, the second other bits, and the third other bits from the copying to each respective buffer.

Example aspect 9: The apparatus of example aspect 1, or any other example(s) described herein, wherein to copy the respective portion of memory addresses from the memory to each respective buffer, the controller is configured to:
copy the respective portion of memory addresses from the memory to each respective buffer of the multiple buffers; and
load the memory addresses of the respective portion of memory addresses into each respective buffer in a different permutation order.

Example aspect 10: The apparatus of example aspect 9, or any other example(s) described herein, wherein:
each buffer of the multiple buffers comprises multiple storage locations;
the controller is configured to load respective instances of the memory addresses of the respective portion of memory addresses into each respective buffer at different storage locations of the multiple storage locations; and
each respective decoder is configured to compute the respective check code by accessing a same set of storage locations of the multiple storage locations of each respective buffer.

Example aspect 11: The apparatus of example aspect 1, or any other example(s) described herein, wherein:
each buffer of the multiple buffers comprises multiple storage locations;
the multiple storage locations have a first quantity of storage locations;
each respective decoder is configured to compute the respective check code using a subset of memory addresses of the respective portion of memory addresses stored in the respective buffer of the respective decoder, the subset of memory addresses having a second quantity of memory addresses; and
the first quantity of storage locations is greater than the second quantity of memory addresses.

Example aspect 12: The apparatus of example aspect 11, or any other example(s) described herein, wherein:
the multiple buffers have a third quantity of buffers; and
the third quantity of buffers is equal to or greater than a number of permutation orders that are possible for memory addresses stored in the multiple storage locations having the first quantity of storage locations.

Example aspect 13: The apparatus of example aspect 1, or any other example(s) described herein, wherein at least some memory addresses of the multiple memory addresses comprise:
a mailbox portion comprising a mailbox indicator indicative of an association between two or more memory addresses; and
a packet portion, the packet portion comprising at least one instance of embedded data or at least one instance of a check code.

Example aspect 14: The apparatus of example aspect 13, or any other example(s) described herein, wherein the controller is configured to:
copy the respective portion of memory addresses from the memory to each respective buffer of the multiple buffers based on the mailbox indicator in each memory address of the multiple memory addresses.

Example aspect 15: The apparatus of example aspect 13, or any other example(s) described herein, further comprising:
a filter coupled to the memory, the filter comprising at least one register configured to store at least one mailbox value, the filter configured to:
   receive a stream of memory addresses comprising a plurality of memory addresses including the multiple memory addresses, the stream of memory addresses comprising mailbox portions in the plurality of memory addresses;
   perform a filter comparison including the mailbox portions of the stream of memory addresses and the at least one mailbox value; and
   load the memory with the multiple memory addresses based on the filter comparison.

Example aspect 16: A method to facilitate using data embedded in address streams, the method comprising:
storing, by a memory, multiple memory addresses that comprise embedded data and a corresponding check code;
copying, from the memory to respective buffers of multiple buffers, respective portions of memory addresses of the multiple memory addresses;
computing, by each respective decoder of multiple decoders, a respective check code based on the respective portion of memory addresses stored in the respective buffer of the multiple buffers corresponding to each respective decoder of the multiple decoders;
comparing, by each respective decoder of the multiple decoders, the respective check code to at least one memory address of the respective portion of memory addresses stored in each respective buffer corresponding to each respective decoder; and
searching, by each respective decoder of the multiple decoders, for the embedded data and the corresponding check code in the multiple memory addresses based on the comparing.

Example aspect 17: The method of example aspect 16, or any other example(s) described herein, further comprising:
filtering a plurality of memory addresses to produce the multiple memory addresses for the storing based on mailbox portions of the plurality of memory addresses and at least one mailbox value.

Example aspect 18: The method of example aspect 16, or any other example(s) described herein, further comprising:
identifying, by a respective decoder of the multiple decoders, the embedded data responsive to the respective check code matching the corresponding check code in the at least one memory address of the respective portion of memory addresses stored in the respective buffer of the respective decoder.

Example aspect 19: The method of example aspect 18, or any other example(s) described herein, further comprising:
interpreting, by a memory device, the identified embedded data as an instruction to perform at least one operation.

Example aspect 20: The method of example aspect 18, or any other example(s) described herein, further comprising:
interpreting, by a memory device, the identified embedded data as an indication of at least one object that is allocated.

Example aspect 21: The method of example aspect 20, or any other example(s) described herein, further comprising:
tracking, by the memory device, memory-side behavior of the at least one object based on the interpreting of the identified embedded data as the indication of the at least one object.

Example aspect 22: The method of example aspect 20, or any other example(s) described herein, further comprising:
storing, by the memory device, historical statistics relating to the at least one object based on the interpreting of the identified embedded data as the indication of the at least one object.

Example aspect 23: The method of example aspect 22, or any other example(s) described herein, further comprising:
predicting upcoming behavior of the at least one object based on the historical statistics; and
adjusting one or more control parameters in advance of the upcoming behavior to increase performance of the memory device.

Example aspect 24: The method of example aspect 23, or any other example(s) described herein, wherein the one or more control parameters relate to prefetching data into a memory-side cache.

Example aspect 25: A method to facilitate using data embedded in address streams at a memory device, the method comprising:
receiving one or more memory addresses comprising embedded data;
detecting the embedded data in the one or more memory addresses, the embedded data comprising at least one operational indication;
identifying the at least one operational indication; and
performing at least one operation based on the at least one operational indication.

Example aspect 26: The method of example aspect 25, or any other example(s) described herein, wherein:
the at least one operational indication corresponds to an allocation of a memory object.

Example aspect 27: The method of example aspect 25, or any other example(s) described herein, wherein:
the at least one operational indication corresponds to a start of a program loop.

Example aspect 28: The method of example aspect 25, or any other example(s) described herein, wherein:
the at least one operation comprises at least one memory-related operation; and
the performing comprises performing the at least one memory-related operation based on the at least one operational indication.

Example aspect 29: The method of example aspect 28, or any other example(s) described herein, wherein the performing the at least one memory-related operation comprises:
communicating to a host device that an allocated address range is adversely impacting memory performance.

Example aspect 30: The method of example aspect 28, or any other example(s) described herein, wherein the performing the at least one memory-related operation comprises:
tracking, by the memory device, behavior of an allocated address range; and
implementing a memory enhancement technique based on the tracking.

Example aspect 31: The method of example aspect 30, or any other example(s) described herein, wherein the implementing comprises:
prefetching data into a memory-side cache based on the tracking of the behavior of the allocated address range.

Example aspect 32: The method of example aspect 25, or any other example(s) described herein, wherein:
the at least one operation comprises at least one non-memory-related operation; and
the performing comprises performing the at least one non-memory-related operation based on the at least one operational indication.

Example aspect 33: The method of example aspect 32, or any other example(s) described herein, wherein the performing the at least one non-memory-related operation comprises:
performing, using a near-memory computing unit, a non-memory-related compute operation.

Example aspect 34: The method of example aspect 32, or any other example(s) described herein, wherein the performing the at least one non-memory-related operation comprises:
executing, using one or more registers of a near-memory computing unit, at least one instruction.

Example aspect 35: The method of example aspect 34, or any other example(s) described herein, wherein the executing comprises:
transmitting, using the one or more registers of the near-memory computing unit, one or more packets onto a network toward another device.

Unless context dictates otherwise, use herein of the word “or” may be considered use of an “inclusive or,” or a term that permits inclusion or application of one or more items that are linked by the word “or” (e.g., a phrase “A or B” may be interpreted as permitting just “A,” as permitting just “B,” or as permitting both “A” and “B”). Also, as used herein, a phrase referring to “at least one of” a list of items refers to any combination of those items, including single members. For instance, “at least one of a, b, or c” can cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c, or any other ordering of a, b, and c). Further, items represented in the accompanying figures and terms discussed herein may be indicative of one or more items or terms, and thus reference may be made interchangeably to single or plural forms of the items and terms in this written description.

### Conclusion

Although aspects of utilizing data embedded in address streams have been described in language specific to certain features and/or methods, the subject of the appended claims is not necessarily limited to the specific features or methods described. Rather, the specific features and methods are disclosed as a variety of example implementations of utilizing data embedded in address streams.

1. An apparatus comprising:
a memory configured to store multiple memory addresses, the multiple memory addresses comprising embedded data and a corresponding check code;
multiple buffers coupled to the memory, each buffer of the multiple buffers configured to store a portion of memory addresses of the multiple memory addresses;
a controller coupled to the memory and the multiple buffers, the controller configured to copy the portion of memory addresses from the memory to each buffer of the multiple buffers; and
multiple decoders, each respective decoder of the multiple decoders coupled to a respective buffer of the multiple buffers, each respective decoder configured to:
compute a respective check code based on the portion of memory addresses stored in each respective buffer; and
search for the embedded data using a comparison including the respective check code and at least one memory address of the portion of memory addresses stored in the respective buffer.

2. The apparatus of claim 1, wherein a respective decoder of the multiple decoders is configured to:
identify the embedded data based on the respective check code matching the corresponding check code that is included as at least part of the at least one memory address of the portion of memory addresses stored in the respective buffer of the respective decoder; and
signal identification of the embedded data responsive to the matching.

3. The apparatus of claim 2, wherein:
the portion of memory addresses stored in the respective buffer comprises a first memory address, a second memory address, and the at least one memory address;
the first memory address comprises a first part of the embedded data;
the second memory address comprises a second part of the embedded data; and
the at least one memory address comprises the corresponding check code.

4. The apparatus of claim 3, wherein to compute the respective check code, the respective decoder is configured to:
apply a checking algorithm to the first part of the embedded data and the second part of the embedded data to produce the respective check code.

5. The apparatus of claim 4, wherein:
the first memory address comprises the first part of the embedded data and first other bits;
the second memory address comprises the second part of the embedded data and second other bits; and
the at least one memory address comprises the corresponding check code and third other bits.

6. The apparatus of claim 1, wherein to copy the portion of memory addresses from the memory to each buffer, the controller is configured to:
copy the portion of memory addresses from the memory to each buffer of the multiple buffers; and
load the memory addresses of the portion of memory addresses into each respective buffer of the multiple buffers in a different permutation order of multiple permutation orders.

7. The apparatus of claim 1, wherein:
each buffer of the multiple buffers comprises multiple storage locations;
the multiple storage locations have a first quantity of storage locations;
each respective decoder is configured to compute the respective check code using a subset of memory addresses of the portion of memory addresses stored in the respective buffer of the respective decoder, the subset of memory addresses having a second quantity of memory addresses; and
the first quantity of storage locations is greater than the second quantity of memory addresses.

8. The apparatus of claim 1, wherein at least some memory addresses of the multiple memory addresses comprise:
a mailbox portion comprising a mailbox indicator indicative of an association between two or more memory addresses; and
a packet portion, the packet portion comprising at least one instance of embedded data or at least one instance of a check code.

9. The apparatus of claim 8, wherein the controller is configured to:
copy the portion of memory addresses from the memory to each buffer of the multiple buffers based on the mailbox indicator in each memory address of the multiple memory addresses.

10. The apparatus of claim 8, further comprising:
a filter coupled to the memory, the filter comprising at least one register configured to store at least one mailbox value, the filter configured to:
receive a stream of memory addresses comprising a plurality of memory addresses including the multiple memory addresses, the stream of memory addresses comprising mailbox portions in the plurality of memory addresses;
perform a filter comparison including the mailbox portions of the stream of memory addresses and the at least one mailbox value; and
load the memory with the multiple memory addresses based on the filter comparison.

11. A method to facilitate using data embedded in address streams, the method comprising:
storing, by a memory, multiple memory addresses that comprise embedded data and a corresponding check code;
copying, from the memory to each buffer of multiple buffers, a portion of memory addresses of the multiple memory addresses;
computing, by each respective decoder of multiple decoders, a respective check code based on the portion of memory addresses stored in a respective buffer of the multiple buffers corresponding to each respective decoder of the multiple decoders;
comparing, by each respective decoder of the multiple decoders, the respective check code to at least one memory address of the portion of memory addresses stored in the respective buffer corresponding to each respective decoder; and
searching, by each respective decoder of the multiple decoders, for the embedded data and the corresponding check code in the multiple memory addresses based on the comparing.

12. The method of claim 11, further comprising:
filtering a plurality of memory addresses to produce the multiple memory addresses for the storing based on mailbox portions of the plurality of memory addresses and at least one mailbox value.

13. The method of claim 11, further comprising:
identifying, by a respective decoder of the multiple decoders, the embedded data responsive to the respective check code matching the corresponding check code in the at least one memory address of the portion of memory addresses stored in the respective buffer corresponding to the respective decoder.

14. The method of claim 13, further comprising:
interpreting, by a memory device, the identified embedded data as an instruction to perform at least one operation.

15. The method of claim 13, further comprising:
interpreting, by a memory device, the identified embedded data as an indication of at least one object that is allocated.

16. The method of claim 15, further comprising:
tracking, by the memory device, memory-side behavior of the at least one object based on the interpreting of the identified embedded data as the indication of the at least one object.

17. The method of claim 15, further comprising:
storing, by the memory device, historical statistics relating to the at least one object based on the interpreting of the identified embedded data as the indication of the at least one object.

18.-20. (canceled)

21. The apparatus of claim 1, wherein the controller is configured to:
copy the same portion of memory addresses of the multiple memory addresses from the memory to each buffer of the multiple buffers.

22. The apparatus of claim 21, wherein the controller is configured to:
load the same memory addresses of the same portion of memory addresses of the multiple memory addresses from the memory into each buffer of the multiple buffers.

23. A method to facilitate using data embedded in address streams, the method comprising:
storing, by a memory, multiple memory addresses that comprise embedded data and a corresponding check code;
copying, from the memory to each buffer of multiple buffers, a portion of memory addresses of the multiple memory addresses;
computing, by each respective decoder of multiple decoders, a respective check code based on the portion of memory addresses stored in a respective buffer of the multiple buffers corresponding to each respective decoder of the multiple decoders;
comparing, by each respective decoder of the multiple decoders, the respective check code to at least one memory address of the portion of memory addresses stored in the respective buffer corresponding to each respective decoder;
detecting, by a particular decoder of the multiple decoders, the embedded data in the multiple memory addresses responsive to the comparing and based on the respective check code matching the corresponding check code in the at least one memory address, the embedded data comprising at least one operational indication; and
performing at least one operation based on the at least one operational indication.
